(19) United States
(12) Patent Application Publication
(10) Pub. No.: US 2010/0089443 A1
(43) Pub. Date: Apr. 15, 2010

(54) PHOTON PROCESSING WITH NANOPATTERNED MATERIALS

(75) Inventors: Theodore M. Bloomstein, Brookline, MA (US); Roderick R. Kunz, Acton, MA (US); Theodore M. Lyszczarz, Concord, MA (US); Vladimir Bulovic, Lexington, MA (US)

Correspondence Address: NUTTER MCCLENNEN & FISH LLP, SEAPORT WEST, 155 SEAPORT BOULEVARD, BOSTON, MA, 02210-2604, US

(73) Assignee: Massachusetts Institute of Technology, Cambridge, MA (US)

(21) Appl. No.: 12/566,278

(22) Filed: Sep. 24, 2009

Related U.S. Application Data
(60) Provisional application No. 61/099,658, filed on Sep. 24, 2008.

(51) Int. Cl. H01L 31/0256; H01L 31/0236; H01L 31/0216; H01L 31/18

(52) U.S. Cl. 136/255; 136/256; 438/82; 977/742; 977/734

(57) ABSTRACT

Methods, devices, and compositions related to organic solar cells, sensors, and other photon processing devices are disclosed. In some aspects, an organic semiconducting composition is formed with nano-sized features, e.g., a layer conforming to a shape exhibiting nano-sized tapered features. Such structures can be formulated as an organic n-type and/or an organic p-type layer incorporated in a device that exhibits enhanced conductor mobility relative to conventional structures such as planar layered formed organic semiconductors. The nanofeatures can be formed on an exciton blocking layer (“EBL”) surface, with an organic semiconducting layer deposited thereon to conform with the EBL's surface features. A variety of material possibilities are disclosed, as well as a number of different configurations. Such organic structures can be used to form flexible solar cells in a roll-out format.

### CROSS REFERENCE TO RELATED APPLICATIONS

The present application claims the benefit of a U.S. Provisional Patent Application bearing Ser. No. 61/099,658, filed Sep. 24, 2008, entitled “Organic Based Solar Cell with Nanopatterned Substrate.” The entire contents of the provisional application is hereby incorporated herein by reference.

### STATEMENT REGARDING FEDERALLY SPONSORED RESEARCH OR DEVELOPMENT

This invention was made with U.S. government support under Department of the Air Force contract number FA8721-05-C-0002. The government has certain rights in the invention.

### FIELD OF THE APPLICATION

The technical field of the present application is directed to materials capable of use with photon processing structures such as organic-based solar cells, and in some instances to nanopatterned substrates for forming such photon processing devices.

### BACKGROUND

In organic based solar cells, absorbed photons more typically produce bound electron-hole pairs (excitons) rather than directly forming free-carriers. Excitons that diffuse to the interface between donor (n-type) and acceptor (p-type) semiconductors readily dissociate, forming a free electron in the n-type material and hole in the p-type material. Once separated, each charge carrier flows towards its corresponding electrode.

Previous work in forming organic-based solar cells includes planar bilayer structures that can be deposited onto a substrate such as an exciton blocking layer (“EBL”). While these structures, among others, have been fabricated, their efficiencies and lifetimes can be limited due to a variety of factors such as material properties and the ability to form structures with the correct dimensions.

For instance, recombination is generally low within the semiconducting layers since the fraction of counter charge (i.e., holes in n-type material and electrons in p-type material) is negligible. In such circumstances, the overall current in the device is primarily determined by the fraction of absorbed photons which form within an exciton diffusion length of the heterojunction. One problem in current technologies is that the absorption lengths in most organic materials are at best only on the order of 50-100 nm over a limited portion of the solar spectrum. This is, however, approximately a factor of five to ten times the characteristic exciton diffusion lengths for most organic semiconducting materials. Thus, only a small fraction of absorbed light participates in free carrier generation.

Accordingly, a need persists for producing more efficient photon processing devices, such as organic solar cells, which do not suffer from these problems and/or others.

### SUMMARY

Methods, devices, and compositions related to organic solar cells, sensors, and other photon processing devices are disclosed. In some aspects, an organic semiconducting composition is formed with nano-sized features, e.g., a layer conforming to a shape exhibiting nano-sized tapered features. Such structures can be formulated as an organic n-type, an organic p-type layer, and/or other material incorporated in a device that exhibits enhanced optical coupling into the active portions of the device relative to conventional structures such as planar layered formed organic semiconductors. The nanofeatures can be formed on an exciton blocking layer (“EBL”) surface, with an organic semiconducting layer deposited thereon to conform with the EBL's surface features. A variety of material possibilities are disclosed, as well as a number of different configurations. Such organic structures can be used to form flexible solar cells in a roll-out format.

Some embodiments are directed to photon processing devices such as organic-based solar cells, which can be optionally configured in a flexible format that can be rolled up and unrolled for operational use. Such devices can include a conductive substrate capable of conducting charge carriers. The substrate, which can be transparent to at least a portion of the solar radiation spectrum, can have any suitable dimension and shape (e.g., a film layer having a thickness sufficient to exhibit nanometer-scaled features). The conductive substrate (e.g., a polymethyl methacylate doped with polyaniline) can include a textured surface, which can have nanometer-scaled features (e.g., features having a size from about 1 nm to about 1 μm) such as one or more protrusions and/or indentations. In some instances, the nanometer-scaled features are configured to direct solar radiation to the semiconductive composition. Such features can be embodied as periodic structures, which can have a pitch, i.e., the distance between the nanostructures, less than about 500 nm, or less than about 300 nm, or less than about a minimum visible solar spectrum wavelength divided by an index of refraction of the conductive substrate. In some instances, the pitch can be greater than about 1 nm, 5 nm, 10 nm, 20 nm, 30 nm, 40 nm, or 50 nm. The cell can also include an organic semiconductive composition having at least a portion conforming to the textured surface of the conductive substrate. The semiconductive composition can include at least one material forming at least a portion of a heterojunction such as a p-n junction or a Schottky metal-semiconductor junction.

In some aspects, the textured surface can include a plurality of tapered structures, which can be two-dimensional and/or three dimensional. The nanometer scaled features (e.g., tapered structures) can exhibit a height to pitch ratio of at least about 0.5:1 or at least about 2:1. The organic semiconductive composition can include at least one n-type material layer and at least one p-type material layer, where one or more of the layers can have a shape substantially conforming with the nanometer-scaled features (e.g., the plurality of tapered structures). Any of the layers, or all, can exhibit a thickness less than about 100 nm, or less than about 50 nm. Electrodes can be electrically coupled to the conductive substrate and the semiconductive composition to form the solar cell. Any of the electrodes can be transparent to at least a portion of the solar radiation spectrum.

Other embodiments are directed to a photon processing device (e.g., an organic solar cell) having an organic semiconductive composition that comprises at least one of a n-type material, a p-type material, and a bulk heterojunction material. For instance, the organic semiconductive composition can comprise at least one of a n-type organic material and a p-type organic material. At least one of the n-type material and p-type material can be configured as a layer conforming to features of a nanotextured surface, the features characterized by a pitch less than about 500 nm. The p-type and n-type materials can be configured to form a single p-n junction, multiple separate p-n junctions, or a single or multiple heterojunctions (e.g., metal/semiconductor). Such an organic semiconductive composition can optionally include any of the features disclosed herein with regard to such compositions in any of the devices disclosed herein.

Further embodiments are drawn to a method of forming a photon processing device such as a photovoltaic cell (e.g., an organic solar cell). A conductive substrate (e.g., a material that can conduct charge carriers such as holes and/or electrons) can be provided, which can include a plurality of elongated structures (e.g., one or more tapered structures), such as those characterized by a pitch less than about 500 nm or less than about 300 nm. An organic semiconductive composition can be coupled to the conductive substrate, the organic semiconductive composition including a n-type material and a p-type material. At least a portion of the organic semiconductive composition can conform with the plurality of elongated structures of the conductive substrate. One or more electrodes in electrical communication with the conductive substrate and the organic semiconductive composition can be attached to form the photovoltaic cell. In some aspects, the conductive substrate can be formed on the surface of an electrode.

In some aspects, the method can include forming a plurality of elongated structures of the conductive structure by imprinting the conductive structure. Such formation can include forming a two-dimensional elongated structure, a three-dimensional elongated structure, or both. The method can also include depositing at least one n-type material layer and at least one p-type material layer such that at least one of the layers contacts the conductive substrate. The layer deposition can take place such that at least one of the layers conforms to the plurality of elongated structures of the conductive substrate (e.g., the entire thickness of the layer follows the undulations of the plurality of elongated structures). The thicknesses of the layers can be less than about 100 nm or less than about 50 nm. Deposition can be performed by using a variety of techniques including organic vapor phase epitaxy and/or thermal evaporation.

### BRIEF DESCRIPTION OF THE FIGURES

The present application will be more fully understood from the following detailed description taken in conjunction with the accompanying drawings (not necessarily drawn to scale), in which:

FIG. 1 is a side cross-sectional schematic view of the layers of an organic solar cell;

FIG. 2A is a side cross-sectional schematic view of the layers of an organic solar cell having nanosized features where the p-type and n-type layers conform with the nanosized features, consistent with some embodiments of the present invention;

FIG. 2B is a side cross-sectional schematic view of the layers of an organic solar cell having nanosized features where the p-type layer conforms with the nanosized features, consistent with some embodiments of the present invention;

FIG. 3 is a side cross-sectional schematic view of a plurality of nanosized structures, consistent with some embodiments;

FIG. 4A is a side cross-sectional schematic view of the layers of an organic solar cell having nanosized features where a bulk heterojunction material is utilized, consistent with some embodiments of the present invention;

FIG. 4B is a side cross-sectional schematic view of the layers of an organic solar cell having nanosized features where a bulk heterojunction material is utilized in another configuration, consistent with some embodiments of the present invention;

FIG. 5 is a side cross-sectional schematic view of the layers of an organic solar cell having nanosized features where an electron conducting exciton blocking layer is textured, consistent with some embodiments of the present invention;

FIG. 6A is a side cross-sectional schematic view of the layers of a photon processing device having nanosized features where multiple p-type and n-type layers are coupled in series, consistent with some embodiments of the present invention;

FIG. 6B is an expanded cross-sectional schematic view of a portion of the layers of the photon processing device shown in FIG. 6A;

FIG. 7 is a side cross-sectional schematic view of the layers of a photon processing device having nanosized features where multiple p-type and n-type layers are coupled to act as parallel p-n junctions, consistent with some embodiments of the present invention;

FIG. 8 is a side cross-sectional schematic view of the layers of an organic solar cell having nanosized features where the electron conducting exciton blocking layer has the nanosized features, consistent with some embodiments of the present invention;

FIG. 9A is a side cross-sectional schematic view of portions of a photon processing device having nanosized features where the anode is formed with a metal bus line embedded in a layer such as a transparent conductive oxide and a conductive polymer, consistent with some embodiments of the present invention;

FIG. 9B is a side cross-sectional schematic view of portions of a photon processing device having nanosized features where the anode is formed with a metal bus line embedded in a conductive polymer and a mixing region, consistent with some embodiments of the present invention;

FIG. 9C is a side cross-sectional schematic view of portions of a photon processing device having nanosized features where the anode is formed with a metal bus line embedded in an exciton blocking material, consistent with some embodiments of the present invention;

FIG. 10 is a side cross-sectional schematic view of a device which is modeled to calculate conductivity values of conductive plastics that can be used with embodiments of the present invention;

FIG. 11A is a side cross-sectional schematic view of a device used to calculate the lateral conductivity of PANI/PMMA compositions, in accord with some embodiments;

FIG. 11B is a side cross-sectional schematic view of a device used to calculate the vertical conductivity of PANI/PMMA compositions, in accord with some embodiments;

FIG. 11C is a top schematic view of a device used to calculate the lateral and vertical conductivity of PANI/PMMA compositions, in accord with some embodiments;

FIG. 12A presents traces of measurements of the lateral conductivity and vertical conductivity as a function of % PANI concentration in PANI/PMMA blends, in accord with some embodiments of the present invention;

FIG. 12B presents an expanded view of the trace of measurements of the vertical conductivity shown in FIG. 12A;

FIG. 13 presents traces of measurements of the lateral conductivity and vertical conductivity as a function of time of exposure to 160° C. bake in minutes for a 7% PANI and PMMA blend, consistent with some embodiments of the present invention;

FIG. 14A presents a cross-sectional schematic view of an embossing tool used to imprint plastic materials with nanotextured features in accord with some embodiments of the present invention;

FIG. 14B presents an underside exploded perspective view of the device shown in FIG. 14A;

FIG. 14BC presents an top-side exploded perspective view of the device shown in FIG. 14A;

FIG. 15A presents a scanning electron micrograph of manufactured two-dimensional wedges formed in silicon that can act as an embossing master, consistent with some embodiments of the invention;

FIG. 15B presents a scanning electron micrograph of manufactured three-dimensional cones formed in silicon that can act as an embossing master, consistent with some embodiments of the invention;

FIG. 16A presents two scanning electron micrographs of manufactured three-dimensional cone structures formed by imprinting a PMMA material with an embossing master, consistent with some embodiments of the invention;

FIG. 16B presents four scanning electron micrographs of manufactured three-dimensional cone structures formed by imprinting a 20% PANI/PMMA material with an embossing master, consistent with some embodiments of the invention;

FIG. 17 presents traces of the measured optical transparency of 100K Dalton PMMA and 5% PANI/100K Dalton PMMA as a function of visible wavelength in accord with some embodiments;

FIG. 18A presents an atomic force micrograph of a PMMA polymer surface exhibiting a RMS roughness value of about 0.37 nm in accord with some embodiments;

FIG. 18B presents an atomic force micrograph of the PMMA polymer surface of FIG. 18A treated with a 1:3 mixture of MIBK/IPA for two minutes and exhibiting a RMS roughness value of about 0.51 nm;

FIG. 18C presents an atomic force micrograph of the PMMA polymer surface of FIG. 18A treated with a 1:3 mixture of MIBK/IPA for sixty minutes and exhibiting a RMS roughness value of about 0.66 nm;

FIG. 18D presents an atomic force micrograph of a 7% doped PANI/PMMA polymer surface exhibiting a RMS roughness value of about 2.9 nm in accord with some embodiments;

FIG. 18E presents an atomic force micrograph of the 7% doped PANI/PMMA polymer surface of FIG. 18D treated with a 1:3 mixture of MIBK/IPA for two minutes and exhibiting a RMS roughness value of about 4.0 nm;

FIG. 18F presents an atomic force micrograph of the 7% doped PANI/PMMA polymer surface of FIG. 18D treated with a 1:3 mixture of MIBK/IPA for sixty minutes and exhibiting a RMS roughness value of about 11.1 nm;

FIG. 19A presents a side view schematic view of a device which is simulated to calculate absorbed power in accord with some embodiments of the present invention;

FIG. 19B presents traces of the absorbed power per unit surface area as a function of depth for the transverse electric and transverse magnetic components for the device simulated in FIG. 19A; the ratio of perimeter increase over a planar surface area is also traced;

FIG. 19C presents traces of the index of refraction as a function wavelength for various materials utilized in the device simulated in FIG. 19A; and

FIG. 19D presents traces of the absorption coefficient (base e) as a function wavelength for various materials utilized in the device simulated in FIG. 19A.

### DETAILED DESCRIPTION OF EMBODIMENTS

Some embodiments of the invention are directed to methods and devices related to an organic semiconductive composition that can conform to a template that exhibits a textured surface having nanometer-scaled features (e.g., features on the scale of about 1 nm to about 1 μm). Such compositions can be utilized in devices such as a solar cell or other photon processing devices (e.g., a sensor and/or photodiode in photon capture, or in photon-emission devices such as those implementing a bias across the electrodes). The nanometer-scaled features can be configured to help enhance solar radiation absorption, while maintaining a thickness of the semiconductor film or films, which participate in exciton and subsequent photocarrier formation, on the order of an exciton diffusion length. In some embodiments, the thickness of the semiconductor film can be about 0.5 to about 3, or about 1 to about 2, exciton diffusion lengths in the film. The nanometer-scaled features can be protrusions and/or indentations, and/or can be tapered structures. As well, the structures can be two-dimensional (e.g., an elongated wedge) or three-dimensional (e.g., one or more cones) in nature. In some embodiments, the features can be periodic, exhibiting a pitch that is less than about 500 nm or less than about 300 nm. In some instances, the pitch can be greater than about 1 nm, 5 nm, 10 nm, 20 nm, 30 nm, 40 nm, or 50 nm. It can be advantageous to choose the pitch to be a distance less than about the minimum wavelength of the solar spectrum to be absorbed divided by the index of refraction of the template. The organic semiconductive composition can include one or more materials that can form at least a portion of a heterojunction such as a p-n junction or metal-semiconductor junction. In some instances, these devices can be fabricated using nanoimprint and thermal evaporation techniques on flexible substrates, which can be high-throughput.

Embodiments of the present invention, such as those described above, can enable an improvement in conversion efficiency of a factor of two or more compared to current photon processing devices (e.g., an organic solar cell with planar layers). In organic planar bilayer solar cells, photons absorbed within approximately 10-40 nm of the interface between the two semiconducting layers contribute to charge generation. Since the optical absorption lengths in organic semiconductors are typically an order of magnitude larger in size, only a small fraction of light is effectively used. As described herein, some embodiments are capable of substantially increasing the fraction of photons absorbed by the use of an organic semiconductor layer conforming to a nanotextured surface. Accordingly, these embodiments can be utilized in devices having enhanced efficiencies and ease of fabrication, enabling greater performance in remotely powered all-organic sensors and portable “off-grid” power generation sources.

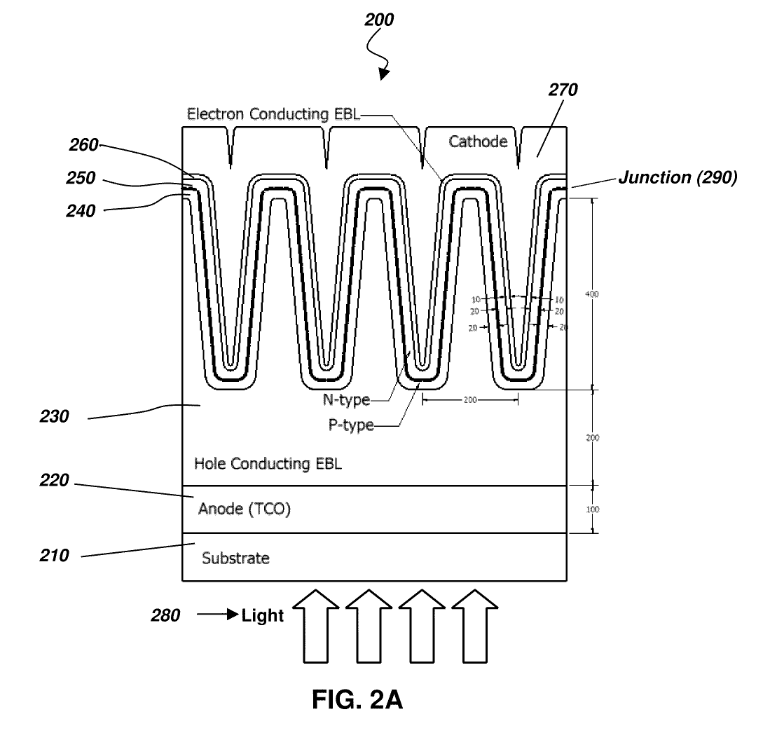

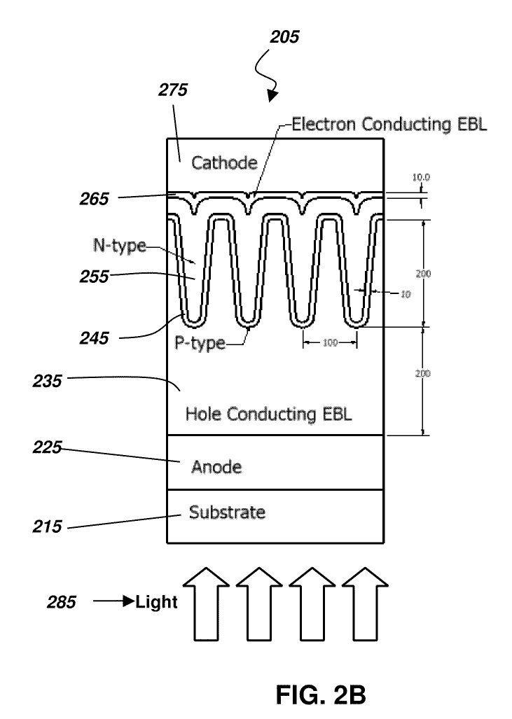

In addition to the improved optical coupling, devices having the conforming nanostructures can also exhibit enhanced electronic transport characteristics relative to interdigitated n- and p-type structures. A folded-over planar geometry as shown in FIG. 2A can place the heterojunction in closer proximity to the semiconductor/EBL interfaces. The shorter path lengths can sustain higher currents before space charge limits carrier flow.

### Operation and Fabrication Principles of Organic-Based Solar Cells

In organic based solar cells, absorbed photons more typically produce bound electron-hole pairs (excitons) rather than directly forming free-carriers. Excitons that diffuse to the interface between donor (n-type) and acceptor (p-type) semiconductors readily dissociate, forming a free electron in the n-type material and hole in the p-type material. Once separated, each charge carrier flows towards its corresponding electrode.

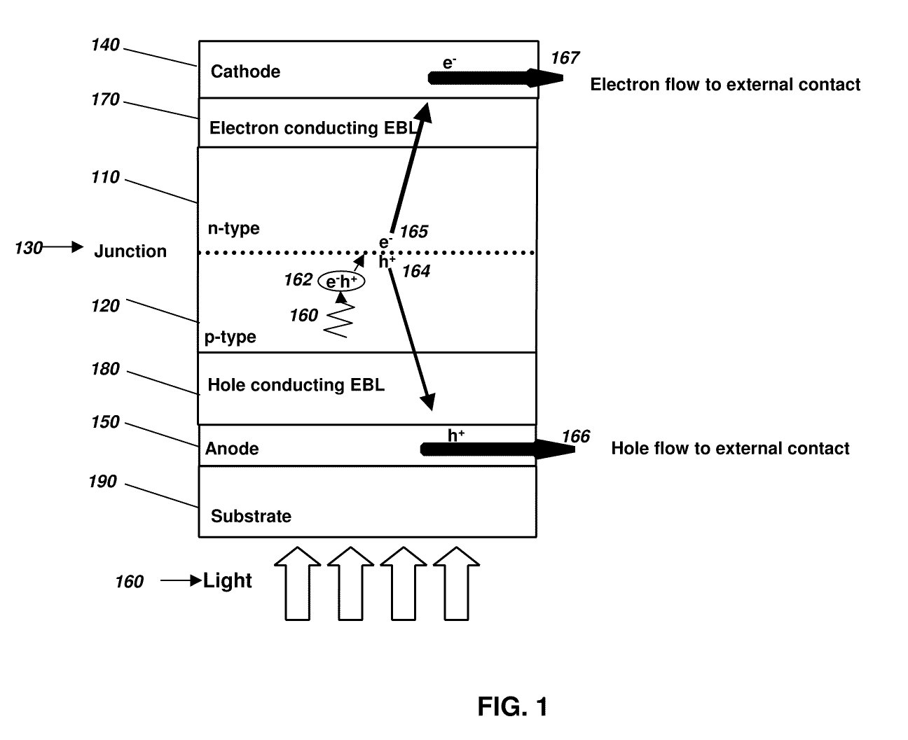

FIG. 1 provides a cross-sectional depiction of a planar, organic-based bilayer heterojunction solar cell. The heterojunction occurs at the interface 130 between organic electron (n-type) 110 and hole (p-type) 120 semiconducting materials. Here, the junction 130 can serve as the exciton 162 dissociation site. By convention, the cathode 140 refers to the electrode which extracts negative charge (electrons 165) while the anode 150 refers to the electrode which extracts positive charge (holes 164). The cathode 140 and anode 150 can support lateral current flow 166, 167 to electrical contacts One of the electrodes (in FIG. 1 it is the anode 150) can be composed of a semi-transparent conductor, e.g., a transparent conductive oxide (“TCO”), to allow light 160 to enter the device. In the highest performance devices to date, transition layers 170, 180 linking the outer electrodes and semiconducting layers are also included. These transition layers 170, 180, herein referred to as exciton blocking layers (“EBLs”), can prevent metal contaminants from migrating into the active semiconducting layers during device fabrication, and limit the degree of exciton recombination at its interface with the semiconductor material (e.g. between 120 and 180, and 110 and 170), in essence reflecting excitons towards the junction 130. In some instances, a suitably chosen EBL improves charge extraction from the semiconductor layer by providing a lower potential barrier to charge flow compared to common electrode materials. It should be understood that the degree to which the a transition layer/EBL acts as an exciton blocker depends on the electronic nature of each material in the device, and in some cases tradeoffs may be necessary to balance the degree to which excitons are blocked, while allowing a charge carrier to be either extracted or injected. While in some situations the transition layer/EBL will act as a poor exciton blocking layer, the transition layers will be identified as an exciton blocking layer rather than a hole or electron transport layer.

Fabrication of devices similar to that depicted in FIG. 1 can occur with each layer deposited sequentially on a substrate 190. Typically, the cathode and anode are deposited by thermal evaporation or sputter deposition. Exciton blocking layers formed from organic polymers, such as poly(3,4-ethylene-dioxythiophene) doped with polysulfonate (“PEDOT:PSS”), can be spin-coated. Low molecular weight molecules such as fullerene (“C₆₀”), copper-phthalocyanine (“CuPc”), and bathocuproine (“BCP”), can be deposited by means of either thermal evaporation or organic vapor phase epitaxy (“OVPE”). In OVPE, an inert carrier gas transports volatized organics to the substrate. In addition to not requiring high vacuum, the resulting stream produces a more conformal coverage over rough surfaces, unlike more classic thermal evaporation techniques where the materials follow unidirectional trajectories from the source.

In organic based solar cells, for example those consistent with the device depicted in FIG. 1, absorbed photons can form excited mobile electron-hole pairs (excitons 162), which readily dissociate at the interface 130 between appropriately chosen n- and p-type semiconductors 110, 120. Once separated, each charge carrier 165, 166 flows towards its corresponding electrode. Recombination is generally low within the semiconducting layers since the fraction of counter charge (i.e., holes in n-type material and electrons in p-type material) is negligible. In such circumstances, the overall current in the device is primarily determined by the fraction of absorbed photons which form within an exciton diffusion length of the heterojunction.

One problem in current technologies is that the absorption lengths in most organic materials are at best only on the order of 50-100 nm over a limited portion of the solar spectrum. This is, however, approximately a factor of five to ten times the characteristic exciton diffusion lengths for most organic semiconducting materials. Accordingly, only a small fraction of absorbed light participates in free carrier generation.

To cope with the inefficient capture of incident radiation, researchers have attempted to utilize a number of techniques to improve organic solar cell efficiencies. For instance, researchers have utilized thin film interference techniques and employed reflective electrodes, concentrators, or diffractive elements to maximize the intensity of light at the interface in planar devices. For example, in one technique described in Cocoyer, C. et al., “Implementation of submicrometeric periodic surface structures toward improvement of organic-solar-cell performances,” Appl. Phys. Lett. 88, 133108 (2006), a bilayer heterojunction was deposited on a lithographically defined diffraction grating, where the underlying substrate and anode (e.g., indium tin oxide) are planarized by spin coating an exciton blocking layer before depositing the organic semiconducting materials. Hence, the organic semiconducting layers are planar. A small increase in efficiency was observed.

Alternatively, designers have attempted to increase the interfacial area between n- and p-type materials using mixtures in the form of discontinuous-phase blends configured as a single layer device. These bulk heterojunction devices rely on a continuous pathway for free carriers dissociated at the interface between the intermixed materials to percolate to the appropriate electrodes. These devices, like the previously discussed planar bilayer devices, do not make full use of incident radiation. The thickness of the active layer cannot be continually increased beyond approximately 100-200 nm to capture more light as material segregation limits the number of continuous pathways for current flow. In addition, significant levels of recombination result from the mutual Coulombic attraction between counterflowing charge propagating through the molecular-scale interleaving pathways.

Self-growth techniques or lithographic patterning have been used to actively shape n- and p-type materials to form structures such as vertically oriented interdigitated arrays of n- and p-type materials using imprint lithography with [6,6]-phenyl-C₆₁-butyric acid methyl ester (“PCBM”) as the n-type material and a thermally deprotectable polythiophene derivative as a moldable, p-type material. One principle challenge has been developing fabrication techniques which maintain a pristine interface between semiconductor layers which otherwise quench excitons and reduce carrier mobilities. Classic lift-off or dry etch transfer steps developed in integrated circuit fabrication expose the interface of the first semiconducting material to etchants or solvents. As well, the counterflowing charges experience a mutual Coulombic attraction. Accordingly, interfacial recombination is expected to increase in deeper structures, limiting overall efficiency gains.

As opposed to shaping the active materials, some purport to construct buried, vertically oriented nanoelectrodes with a bulk heterojunction material filling the gap between the electrodes. Organic solar cells have been fabricated on directly on roughened indium tin oxide (“ITO”). However, the performance has been poor. It is believed that ITO can slowly oxidize conjugated organic semiconductors, degrading electrical performance.

Accordingly, a need persists to improve the performance of organic based solar cells.

Structures Having Organic Semiconducting Layers Conforming with a Nanotextured Surface

Some embodiments of the invention are directed to photon processing structures, e.g., an organic solar cell, that can utilize an organic semiconductive composition that conforms to a shape exhibiting a nanometer-scaled features, i.e., a nanotextured shape. For instance, the semiconductive composition can be embodied as a layer that conforms with a nanotextured shape, e.g., the entire thickness of the surface conforms to a shape exhibiting nanotextured features. The features can be nano-scale indentations and/or protrusions.

The organic semiconductive composition conforming to a nanotextured shape can be embodied in many different manners. In some particular embodiments, a device can include multiple semiconducting layers (e.g., one layer having a n-type material and one layer having a p-type material), which can be deposited over a high density array of nanofeatures imprinted in a substrate such as a semi-transparent conductive plastic or other charge-carrying conductive substrate. The nanofeatures can be nanosized indentation and/or protrusions having a variety of shapes. For example, the nanofeatures can include two or three-dimensional tapered structures such as nanotrenches or nanocones. In general, a tapered structure refers to a structure whose cross-sectional area tends to generally increase (e.g., continuously) as one travels along an elongate axis of the structure. For protrusion structures, the tapered structure can attach to a body at its higher cross sectional area end. For indentation structures, the tapered structure can exhibit its smallest cross sectional area at the deepest point of the indentation. At least one of the layers can exhibit a thickness less than about 100 nm or less than about 50 nm. A greater fraction of light can be absorbed at the interface, e.g., due to the increased surface area of the junction. Enhanced performance can occur in high aspect ratio cones with 100-300 nm lateral features. The height to pitch ratio can be greater than about 1:1. At these dimensions, the full terrestrial spectrum can scatter into the semiconducting layers.

In some particular embodiments, the interfacial density of a device (e.g., an organic solar cell) is increased by depositing multiple semiconducting layers over a nanoimprinted multi-dimensional tapered exciton blocking layer fabricated on top of a higher conductive film (e.g., a planar shaped electrode). Such embodiments can differ from related structures in known organic solar cells in a number of respects. For instance, such embodiments can utilize a bilayer organic heterojunction rather than inorganic/organic combinations. The exciton blocking layer can be patterned rather than the supporting substrate or electrode. Organic n- and p-type materials need not necessarily be interleaved, as is the case in the vertically oriented interdigitated arrays either lithographically defined or fabricated through self-growth techniques. For instance, one or more organic semiconductor materials can be used to form one or more layers that conform to at least a portion of the texture of the exciton blocking layer, e.g., forming a folded over layer where the entire thickness of the layer conforms with the portion of the exciton blocking layer. As well, the active semiconductor layers are not necessarily roughened by optimizing OVPE deposition conditions, although some embodiments could potentially benefit by employing this technique.

To further illustrate some aspects of the invention, a schematic representation of some embodiments are shown in FIGS. 2A and 2B. In some instances, except for the addition of a nanoimprint step, fabrication of a solar cell structure can follow in a similar fashion to a planar device. The description here only depicts some particular embodiments of the invention. Other material systems and variations are described herein.

With respect to FIG. 2A, starting from a planar, transparent substrate 210, an anode 220 can be deposited using a TCO such as ITO. The anode can then be coated with a semi-transparent conductive nanoimprint material (e.g., polymer resist), which will act as the hole conducting EBL. Two dimensional (e.g., wedges) or three dimensional (e.g., cones) tapered structures can then formed in the material producing a shaped exciton blocking layer 230. Organic semiconducting p- and n-type materials 240, 250 can be deposited over the shaped EBL 230, e.g., by evaporating materials over the shaped EBL without breaking vacuum to maintain a pristine interface at the heterojunction 290 of the device where exciton dissociation primarily occurs. Following deposition of the active semiconductor layers, the exciton blocking layer 260 and the cathode 270 can be deposited. Finally, electrical contacts (not shown) can be bonded to the anode 220 and cathode 270. Additional encapsulation can optionally be used to limit environmental contaminants from degrading the active semiconductor layers.

One aspect of some embodiments of the invention relates to the relaxation of conductivity requirements in the exciton blocking layers when a layer conforms to a nanotextured shape (e.g., a shape having nanosized and/or sub-visible wavelength sized tapered features). For instance, each structure (e.g., a two-dimensional wedge or three-dimensional cone) can conduct a moderate current over a limited length scale; the underlying electrode can transport the accumulated currents for each cone or wedge laterally to external contacts. Because of the reduced conductivity requirements, the conductive polymers do not have to be used in their neat forms, but rather their conductive plastic analogs can have sufficient conductivity. For instance, in polyaniline doped plastics, the conductive polymer forms continuous interpenetrating networks rather than phase separating into aggregates in the host matrix. Since only trace levels of conductive polymer dopant can be utilized in these materials, the resolution and transparency properties can be dictated primarily by the host matrix.

Use of tapered structures can improve coating conformality by reducing shadowing during the organic semiconductor and subsequent electron transporting EBL deposition step. As well, tapered geometries are well suited to nanoimprint techniques. The reduced aspect ratios of such structures can lower resistance forces when utilizing imprint techniques to form structure shapes. Such structures can also reduce the contact area during mold extraction, which can potentially reduce distortions to the replica and damage to the master.

The structure in FIG. 2B provides an illustration of alternative embodiments where only one of the organic semiconducting layers 245, the p-type layer, conforms with the surface morphology of the hole conducting EBL 235. The n-type layer 255 can fill, or substantially fill, the gaps formed by the p-type layer 245, with the electron conducting EBL 265 and cathode 275 having more planar layer like geometries relative to what is depicted in FIG. 2A. Though the n-type layer is much thicker in the device of FIG. 2B, a large differential in carrier mobilities between the semiconductor materials can partially mitigate the effects of longer path lengths. For instance, the electron mobility of C₆₀ is greater than the hole mobility of other common p-type organic materials such as CuPc by a factor of approximately 100 times.

FIGS. 2A and 2B provide some typical dimensions of a device consistent with some embodiments of the present invention. The thickness of each semiconducting layer can be in a range of about the layer's exciton diffusion length±50%, 40%, 30%, 20%, 15%, 10%, 5%, 3%, 1%, or 0.1%. This can potentially increase the number of excitons reaching an interface and/or reduce the optical losses in thicker films. Schottky metal-semiconductor cells can also be fabricated over the shaped EBL 230, 235. In this case, a metal is substituted for one of the semiconducting layers 240 or 245, and is sufficiently thin to limit optical losses. For typical metals used such as aluminum, the thickness can be less than 10 nm.

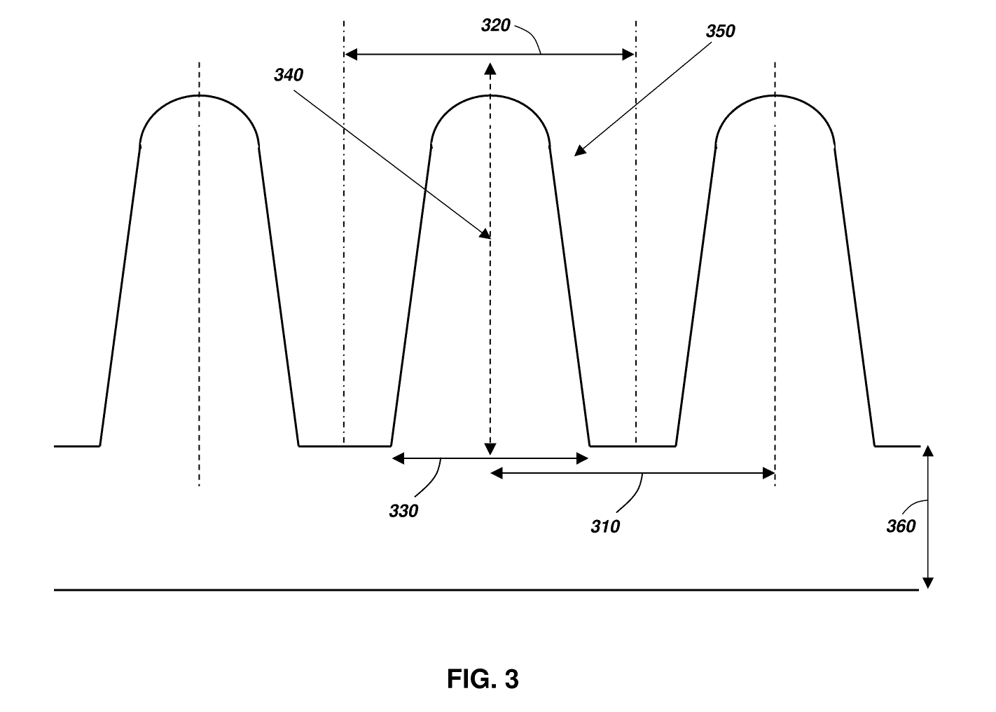

In some embodiments, enhanced performance can also occur when the lateral features of the nanostructured EBL are at, or below, the guidance condition for beam propagation in the structure. FIG. 3 presents a schematic view of an exemplary periodic set of three unit cells 320 of nanostructures consistent with some embodiments of the present invention. In some instances, the enhanced performance also occurs when the aspect ratio of the cross sectional height 340 to width 330 of the nanostructure 350 (e.g., a cone or wedge) is equal to or greater than about 0.5:1. The guidance condition can be estimated as the point at which the pitch 310, i.e., the distance between the nanostructures 350, is below the minimum wavelength of the terrestrial portion of the solar spectrum divided by the refractive index of the material used to form the EBL. At this length scale or smaller, the EBL structure can scatter the full spectrum of incident light into the exciton generating semiconducting layers. The absorbed power at a semiconductor heterojunction will therefore scale with the increase in surface area of the patterned EBL structure. Larger lateral features require larger aspect ratios to produce the equivalent efficiency enhancements, as light is partially guided rather than effectively driven out of the EBL. Optical losses can also increase in larger scale structures from the longer path lengths. In addition, larger levels of semi-absorptive dopants that will be required in the conductive plastic to offset ohmic losses from the higher current levels drawn per tapered feature.

Layer thicknesses at or below about 200 nm to about 500 nm are believed to not significantly degrade either throughput or absorption losses, and are well within the dimensional scales used in nanoimprint, even when imprint processes are utilized and leave a residual layer 360. The thickness of the other remaining layers can be similar to the values used in planar devices. The anode thickness can be chosen to balance optical absorption losses against electrical series resistance losses. Similar thicknesses are used for the cathode. The electron conducting exciton blocking layer can be on the order of 10-20 nm thick.

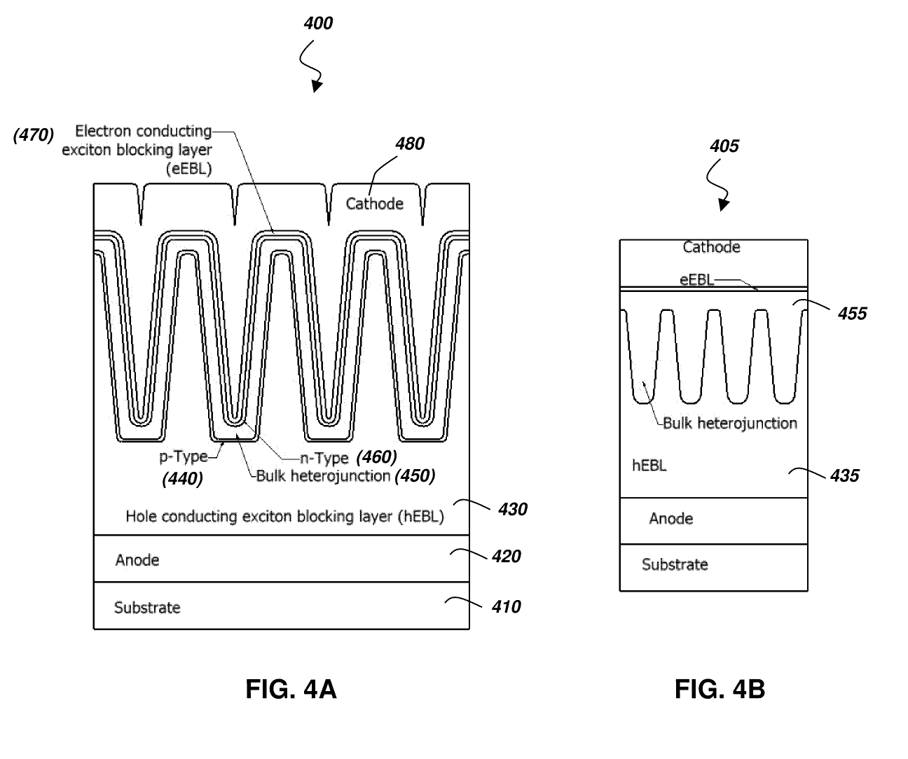

Other embodiments of the present invention are directed to photon processing devices that can utilize bulk heterojunction materials as the active organic semiconductor, which can be deposited on a nanotextured surface such as an EBL. Some of these embodiments are described with reference to FIGS. 4A and 4B. As shown in FIG. 4A, an anode 420 is deposited on a substrate 410. A hole conducting EBL 430 having nanotextured features is deposited on the anode 420. P-type layer 440, bulk heterojunction layer 450, n-type layer 460, and electron conducting EBL 470 are deposited on, and conform with, the nanotextured features of the hole conducting EBL 430. The cathode 480 is then deposited on the top of the electron conducting EBL 470, completing the structure 400. Per unit thickness, the amount of light irradiating the bulk heterojunction material increases on nanotextured structures. Thus, thinner layers can be used to maintain a greater fraction of continuous pathways for photogenerated charge to reach the appropriate electrode. As shown in FIG. 4B, a device 405 can be constructed without the use of n-type layers and p-type layers, utilizing only bulk heterojunction material layer 455. It should be noted that the heterojunction layer 455 can fill the intersticies of the hole conducting EBL layer 435. Thus, conformation of the heterojunction layer 455 with the nanotextures of the EBL 435 is not required, though the layer 455 is desirably thin enough to maintain the greater fraction of continuous pathways by which the carriers can travel in the heterojunction material. In other embodiments, the bulk heterojunction layer can conform with the nanotextured EBL. For many bulk heterojunction materials, electron carrier mobilities are typically substantially higher. Accordingly, the differential can be partially mitigated by providing a larger contact surface for the hole conducting exciton blocking layer.

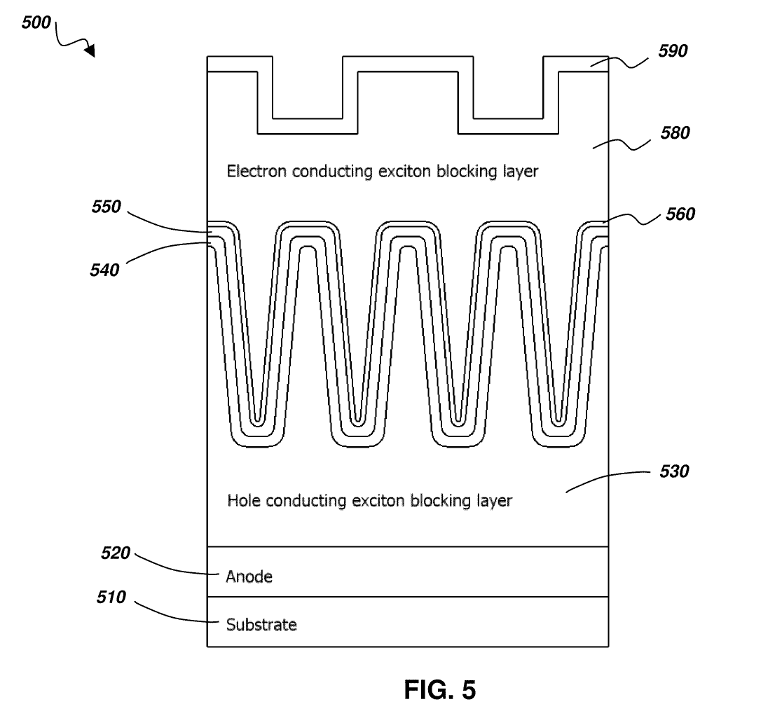

In some embodiments, the electron conducting EBL can be textured, e.g., using imprint techniques, which can potentially improve light capture in the device. For instance, FIG. 5 shows a grating pattern formed in a electron conducting EBL 580 and coated with cathode 590. Such a texture can be used to redirect reflected light at oblique angles back through the structure 500. In some instances, the patterned features may not have sub-wavelength dimensions, nor may they be as highly tapered relative to what could be used to texture the hole conducting EBL 530. As inferred above, a number of different types of techniques, including those known to one skilled in the art, can be used to provide texturing in the electron conducting EBL (e.g., imprinting, lithographic techniques, anisotropic film growth, or selective chemical etching).

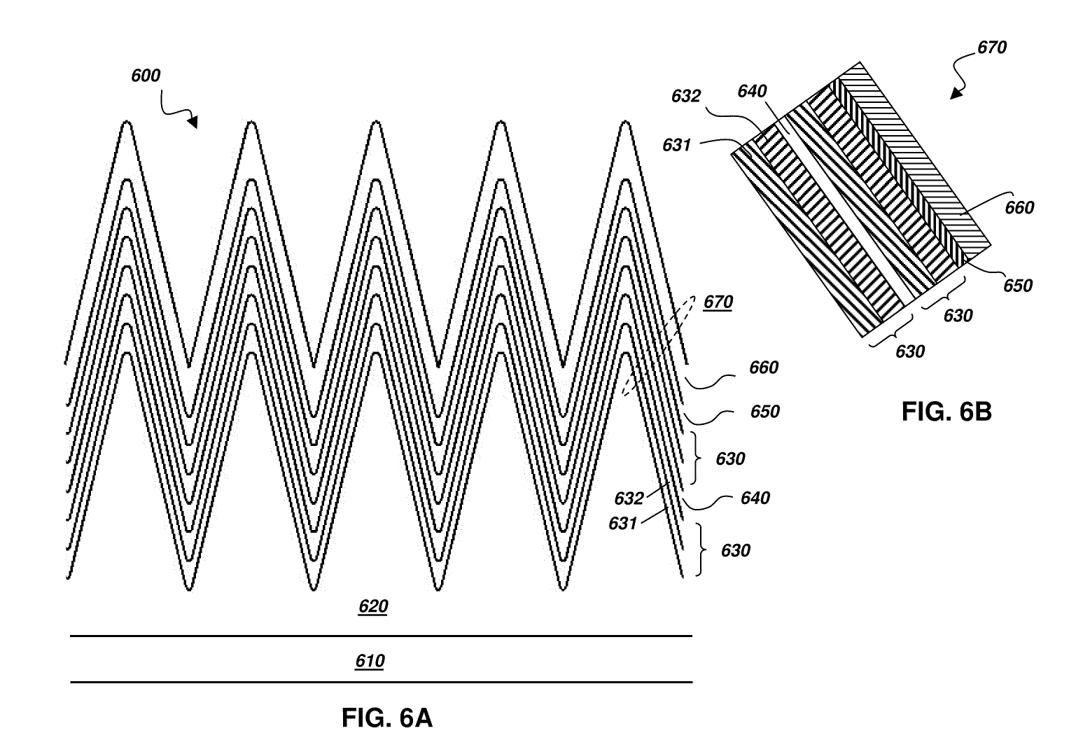

In other embodiments, additional junctions may be added to a device to capture a greater fraction of radiation, which can potentially further increase efficiency. In one embodiment, as exemplified in FIG. 6A, with a more detailed layer view of the circled area 670 in FIG. 6B, a series of ensemble layers 630 are repeatedly deposited sequentially on an EBL 620 that contacts an anode 610. Each ensemble layer 630 comprises a p-type material 631 and a n-type material 632. Intervening floating electrode 640 is deposited between each bilayer 630 to serve as a recombination site for electrons and holes, which can prevent the build-up of charge. An electron conducting EBL 650 and cathode 660 are disposed on the top of the device 600.

In another embodiment, the present architecture can be configured with multiple parallel junctions with only outer electrodes, rather than patterning separate intervening electrical contacts between each adjoining bilayer. Each junction acts in parallel allowing currents to add, rather than in a series configuration where the photoconversion efficiency of the poorest performing bilayer junction sets overall device performance. No inverted heterojunctions exist in this embodiment where charge can build-up removing the need for metal interlayers.

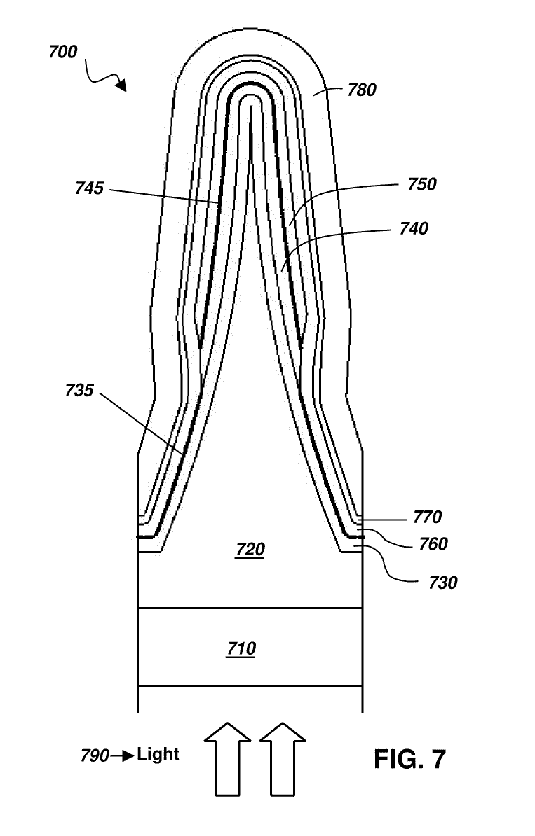

A schematic representation of one exemplary embodiment is shown in FIG. 7, depicting a cross sectional view of one unit cell of a coated nanostructure. After providing a patterned nanotextured hole conducting exciton blocking layer 720 on an anode 710, a conformal coating of a p-type organic semiconductor, p_{L} 730, can be deposited using a material which absorbs at longer wavelengths. P-type and n-type organic semiconductor films, (p_{H} 740 and n_{H} 750), which absorb at shorter wavelengths, are then deposited, for example, sequentially using oblique incident thermal evaporation techniques. In this fashion, only the upper portions of the tapered structure 700 is coated. A thin film of n-type semiconducting material, n_{L} 760, is deposited, which primarily absorbs at longer wavelengths. An electron conducting exciton blocking layer 770 and cathode 780 are then deposited, optionally followed by an encapsulant.

By appropriately tailoring the geometry, the nanostructure 700 can act as a filter, spatially rejecting different portions of the spectrum for incident light 790. Longer wavelength light can be preferentially scattered out of the hole conducting exciton blocking layer 720 along the bottom portion of the nanostructure for wavelengths above the guidance condition set by the lateral extent of the base of the nanostructure. Excitons formed in n_{L} 760 and p_{L} 730 are dissociated at junction J_{L} 735. Shorter wavelength light propagates deeper into the hole conducting exciton blocking layer 720, where it eventually scatters out the top portion of the nanostructure 700. Excitons formed in n_{H} 750 and p_{H} 740 are split at junction J_{H} 745. In this fashion, each n- and p-type pair which forms a junction is irradiated by the portion of the solar spectrum tuned to their primary absorption bands. Electrons produced at the buried interface, J_{H} 735, flow through n-type material (n_{L} 760 and n_{H} 750) while holes flow through p-type material (p_{L} 730 and p_{H} 740). No metal interlayers to assist in charge recombination are required as no reverse heterojunctions exist where charge can build up. Using the same principle, additional multilayer parallel junctions can be built up. In this case, oblique angle depositions can be performed at least twice at different angles. In principle, parallel junctions can be stacked in series, using intervening metal layers. In all cases, similar procedures using electromagnetic modeling and growth rate data can be used to optimize the structure of the EBL as in the case of a bilayer device.

Other modifications can be utilized with embodiments consistent with the present invention. For example, the devices shown in FIGS. 2A and 2B can be manufactured in a somewhat inverted fashion where a cathode can be disposed on the substrate (e.g., an absorptive substrate) with a electron conducting EBL contacting the cathode and being shaped to have the nanotextured surface. Accordingly, the n-type material contacts the electron conducting EBL and conforms with the nanotextured surface. It is understood that other embodiments described herein with a nanotextured hole conducting EBL can be practiced with a similarly shaped nanotextured electron conducting EBL, with the other structures appropriately arranged to allow operation of a device.

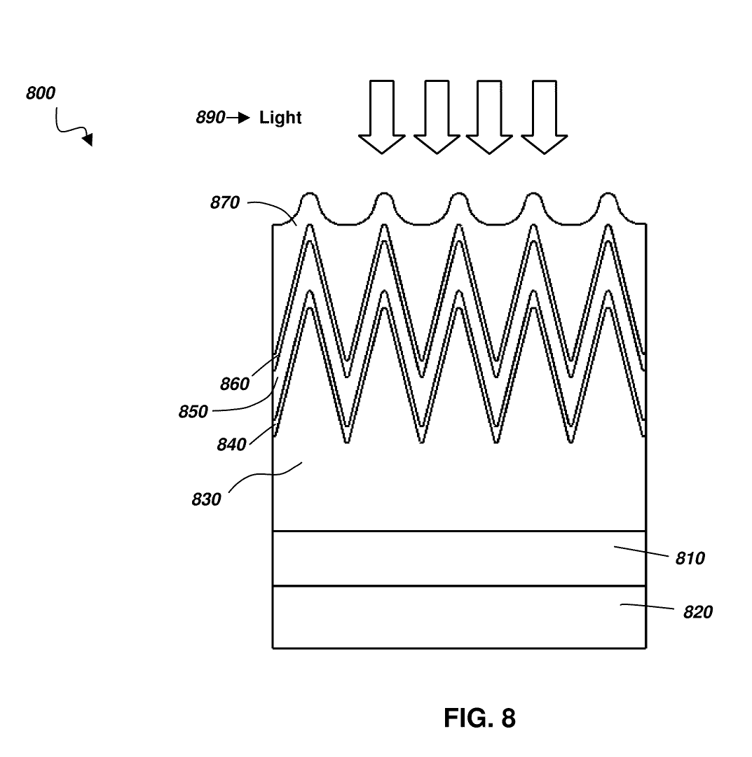

One example of such a modified structure is depicted in FIG. 8. A solar capture device 800 can be irradiated from the top side by light 890. In this case, the cathode 810, e.g., a reflective metal, is deposited on a substrate 820 that can be opaque. After defining a textured surface in the conductive plastic 830, n-type 840 and p-type 850 materials are sequentially deposited. After capping these layers with a hole conducting exciton blocking layer 860, the anode 870 is deposited using a material such as a transparent conductive oxide.

Other embodiments can be drawn to devices that include a Schottky junction. For instance, a semiconductor material, for example as utilized in any of the embodiments disclosed herein, can be switched with an appropriate metal material (e.g., a thin metal layer such as aluminum) to form a junction. Such junctions can function to form a variety of useful structures, including those known to one skilled in the art.

### Flexible Photon Processing Devices

Some embodiments of the present invention are directed to photon processing devices such as organic solar cells, which can be formed as flexible structures. One interest in utilizing organic semiconductors is that the processing temperatures may be maintained below 180° C., enabling the use of flexible inexpensive substrates that can be adapted for roll-to-roll processing. An extensive infrastructure already exists for multi-source roll-to-roll thermal evaporators in the coatings and capacitor fabrication industries. These tools can also used to deposit transparent conductive oxides (“TCOs”) and capabilities are already developing to deposit thin-film barrier layers for organic light emitting diodes (“OLEDs”). Tools with physical enhanced chemical vapor phase deposition (“PECVD”) capability are also available, so that roll-to-roll systems can be configured for organic vapor phase epitaxy (“OVPE”) where an inert carrier gas is added to improve coating uniformity. The imprint step is also amenable to higher throughput roll-to-roll processing since no high resolution alignment step is required. The nanoimprint step is also not expected to significantly degrade yields. Since the active semiconducting layers can be deposited over the conductive plastic, defects which may occur, e.g., from particles transferred from a mold master to the device or incomplete patterning from inhomogeneities in the plastic film, are not expected to short-circuit the device. Rather the minimal loss in surface area is more than compensated by utilizing multi-dimension nanoimprinted structures to increase interfacial density for exciton separation.

An estimate of flexible solar cell production throughput can be performed by estimating the rate of each of the stages: substrate preparation (patterning bus liens and depositing a TCO); device fabrication (coating a nanoprint resist, patterning the EBL, depositing organics, and depositing a cathode); and packaging (bonding contacts and depositing a barrier film). Based on values taken from the literature for industrial scale roll-to-roll processes, organic material deposition is believed to be the limiting step for comparison of patterning rates. Of the various steps, TCO deposition for 100 nm scale films is believed to be the next to slowest step. Rates for patterning the bus line can be estimated assuming the patterning system has 100 μm resolution. Barrier layers are assumed to be an alternating stack of a 50 nm thick inorganic and 1 micron thick organic layer, repeated 5 times. The inorganic layer provides the primary barrier to oxygen and moisture penetration, while the organic material fills pinholes. The organics are deposited by atomizing an acrylic monomer and polymerizing the material, either using an electron beam or UV excitation. Deposition and curing rates for the organic portion are assumed to be similar to that of fluid coaters as a worst case estimate. This translates into an area coverage rate of 2×10⁶-10⁷ m²/yr (for five layers) assuming a 2.5 m wide sheet. For comparison, the deposition rate of 50 nm thick Al₂O₃ is approximately 10⁸ m²/yr (for five layers).

Assuming a value of 0.1 nm/s, an organic based OVPE system capable of depositing three materials over a 2.5 m wide×1 m length area could coat a 100 nm thick tri-layer (n/p/EBL) over ˜10⁵ m² per year. To put this number in perspective, a high-throughput 300 mm optical lithography scanner operating continuously at 150 wafers/hour will produce an equivalent surface area coverage.

A modest thermal imprint tool can be capable of maintaining similar throughputs. Assuming 100 nm diameter pillars that are 100 nm deep can be patterned in PMMA using 5 sec imprint times by only heating the mold master, a single press with a 150 mm×150 mm master would achieve similar throughputs as the deposition system excluding any additional overhead. Using a thermal nanoprint roller based process, and using separate heater and cooling rollers, thermally imprinted sub 100 nm scale features at 140° C. in polystyrene can be achieved at 5 cm/s feed rates. Thus, for a 2.5 m wide drum, the estimated surface coverage is 4×10⁶ m²/yr.

Since the disclosed embodiments can be fabricated at low temperatures on flexible substrates, this technology can be used in remote power generation. Even at 5% efficiency, a 10 ft×10 ft solar “blanket” could provide up to 500 W of power during daylight conditions, augmenting the capabilities of mobile troops or providing temporary power for disaster relief personnel, victims, and facilities.

It is believed that organic based solar cells, in accord with some of the embodiments, can potentially compete with amorphous silicon (a-Si) cells for temporary “off-grid” power production. An example is in disaster relief, where lifetimes on the order of several months could be adequate to provide backup power until permanent infrastructure is restored or replacement cells delivered. Laboratory based a-Si versions are approximately 5% efficient for thin devices (˜300 nm), while commercial versions have 3-4% efficiencies. Based on simulations, similar efficiencies are possible over an expanded set of more robust organic semiconducting materials. The lifetimes of OLED's suggest that sufficiently robust organic materials for solar cells may exist which can last over extended periods. Thin-film encapsulants have already demonstrated similar performance levels as glass packages over six months.

### Materials and Processes for Device Construction

A variety of materials and processes can be utilized in constructing various portions of devices disclosed herein including any materials utilized in a manner consistent with embodiments of the present invention. In this section, a description of some such materials are described with respect to the schematics in FIGS. 2 and 3. It is understood, however, that materials that can be utilized with structures shown in the FIGS. 2 and 3 are not necessarily limited to those materials explicitly described, and that the materials disclosed are not limited for use with embodiments exclusively depicted in the figures.

Table 1 below provides a table of materials that are discussed within the present application, and include abbreviations that are utilized throughout the text.

TABLE 1
Summary of Chemical Compounds and Abbreviations

| Abrev. | Chemical Name | Structure |
|---|---|---|
| CuPc | copper-phthalocyanine | 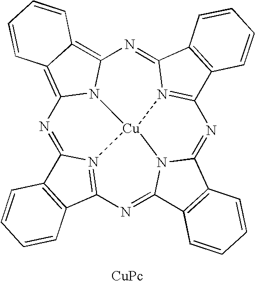 |
| C₆₀ | fullerene | 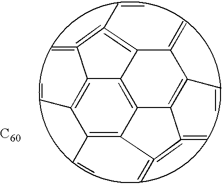 |
| PTCBI | 3,4,9,10- perylenetetracarboxylic bis-benzimidazole | 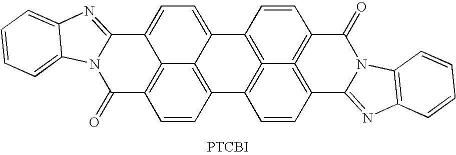 |
| PTCDI | 3,4,9,10- perylenetetracarboxylic diimide | 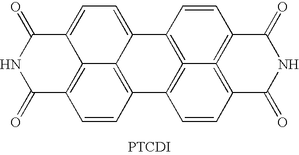 |
| PTCDA | 3,4,9,10- perylenetertracarboxylic dianhydride | 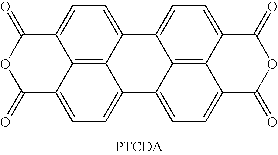 |
| Pn | pentacene | 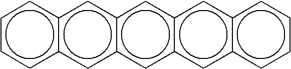 |
| V4T V5T | 5-vinyl-2,2′:5′,2″:5″,2′′′- quarterthiophene 5-vinyl-2′:5′,2″:5″,2′′′:5′′′,2′′′′- quarterthiophene | 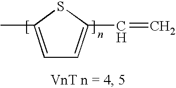 |
| BCP | bathocurproine | 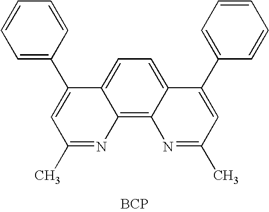 |
| PEDOT: PSS | poly(3,4-ethylene- dioxythiophene) doped with polysulfonate | 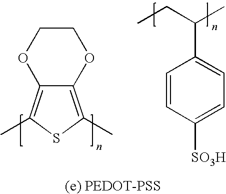 |
| PANI- CSA | Polyaniline protonated with sulfonic acid | 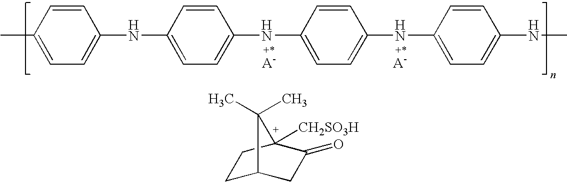 |

As depicted in FIGS. 2A and 2B, a substrate 210, 215 can provide an underlying physical support structure on which the remainder of a device 200, 205 is fabricated. A substrate can be sufficiently transparent to allow incident radiation 280, 285 to penetrate into the organic semiconducting layers. In some instances, a rigid glass material can be utilized. In addition, since organic electronic materials are typically processed at temperatures below 180° C., high temperature plastics or flexible thin-films such as poly(ethylene terephthalate) (“PET”) and poly(ethylene naphthalate) (“PEN”), which are amenable to low-cost roll-to-roll processing, may also be used.

The anode 220, 225 can support lateral flow of holes to external contacts. Common materials for the anode can include transparent conductive oxides (“TCOs”) such as indium tin oxide (“ITO”) and fluorine doped tin oxide. Thicker anodes can reduce the electrical series resistance losses to external contacts, but can increase optical losses, since common anode materials are typically semi-absorptive. In some embodiments, the thickness of the anode can be in a range from about 20 nm to about 250 nm. For example, thicknesses on the order of 100 nm are typically used to balance the two effects. Thin conductive metal films may also be used. While the anode can have a planar geometry in some instances, patterned, metal grid lines can also be employed with dimensions chosen to optimize optical throughputs and minimize series resistance losses.

Conductive organic polymers such as poly(3,4-ethylene-dioxythiophene) (“PEDOT”), PEDOT in glycerol or other high boiling solvents, PEDOT based derivatives, polyaniline (“PANI”), polyaniline derivatives, or other conductive plastics can also used as an anode material. In practice, if organic based materials are used for the anode, the coating solvent for the hole conducting exciton blocking layer can be tailored to prevent substantial intermixing with the anode, maintaining the integrity of each layer. For example, m-cresol, the coating solvent for one of the proposed materials for the hole conducting exciton blocking layer, does not readily dissolve thin films of water soluble PEDOT:PSS (Aldrich #560596-25G). PANI/poly(methyl methacrylate) (“PMMA”) conductive plastics dissolved in m-cresol or less polar organic solvents are also not expected to intermix with water soluble PANI derivatives. For other organic combinations, one skilled in the art can formulate solvent systems for the conductive plastic with the appropriate polar and dispersive properties to prevent intermixing with the underlying anode structure.

As depicted in FIGS. 2A and 2B, hole conducting exciton blocking layers 230, 235 can provide an electrical pathway for charge generated in the organic semiconductor layers 240, 245 to flow to the anode 220, 225. The EBL can also provide a barrier layer to prevent contaminants (e.g., from an anode) from degrading the semiconducting layers. Since the anode supports lateral current flow over larger distances to the external contacts, charge flow in the EBL can be over a relatively short distance. Thus, the overall conductivity of the EBL can be lower than typically associated with common metal or inorganic based transparent conductive oxides. In some embodiments, the EBL material can be controllably patterned at high resolution and at high aspect ratios to enhance delivery of the incident radiation into the active semiconducting layers. In addition, the EBL material can be sufficiently transparent to enhance incident radiation onto the active organic semiconducting layers 240, 245, 250, 255.

Some embodiments utilize conductive plastics derived from polyaniline as at least a portion of the material for an exciton blocking layer (e.g., a hole conducting EBL). For example, a protonated PANI can be used in a blend with in an inert host matrix such as poly(methyl methacrylate) (“PMMA”). As utilized herein, the percent PANI in PMMA or percent PANI dopant in PMMA refers to the weight percent of PANI in the blend, whose balance can be substantially PMMA. Polyaniline's work function is well aligned to many common organic semiconducting materials, which can reduce barriers to charge extraction, and it has been used as a hole injection layer in organic light emitting diodes. PMMA is a common thermal nanoimprint resist and has demonstrated resolutions down to 10 nm, and accordingly can act as the host matrix. In some embodiments, low levels of conductive PANI dopant can be used to achieve enhanced conductivity for the EBL. Accordingly, the host matrix can primarily determine the patterning properties (e.g., mechanical imprint) of the mixture in these circumstances.

Experiments have demonstrated that conductive thermoplastic solutions of PMMA doped with PANI protonated with camphor sulfonic acid (“CSA”) and dissolved in m-cresol possess suitable bulk conductivity and temperature stability, patterning fidelity, and transparency for the present application. The photoresponse of planar devices fabricated on PANI/PMMA thin-films indicate that such a material system should be usable with the configurations revealed in the present application. Based on an estimate using Ohm's Law for a representation of the geometry and parameters, a conductivity ˜10⁻⁴/Ωcm can be sufficient to maintain bulk ohmic losses below 1% for typical operating potentials within a device. Although published results report PANI doping levels well below 1% can be adequate, experiments have indicated a strong anisotropy in the conductivity. Accordingly, higher levels of dopant than otherwise expected from the published literature can be utilized. PANI/PMMA blends can be patterned at sub-100 nm lateral dimensions at aspect ratios of at least 1:1. Accordingly, EBL material including dopant levels between 5%-20% for a PANI/PMMA blend can be patterned at high resolution over relatively large areas. Higher levels of dopant can also be utilized, which can improve conductivity, resulting in more efficient electrical charge transport. However, higher level can also result in more light is absorbed within the EBL which does not ultimately participate in exciton formation, which can reduce overall quantum efficiencies. In addition, the fraction of textured area, which results in enhanced photoresponse, may also be reduced at too high a dopant level. In some instances, the film homogeneity for 10K MW PANI/100K MW PMMA blends cast in m-cresol has been found to be superior to blends comprised of 65K MW PANI/100K MW PMMA, though the later can be utilized as well.

PANI/PMMA blends can be formulated in a variety of manners, using various combinations of alternative protonating agents and solvents. Other host matrices such as polycarbonates, polyacetonitriles, polyvinylalcohols, or polystyrenes may also be used in place of, or augmenting, the PMMA. In some embodiments, plasticizers can be added, which can lower the percolation threshold and increase the conductivity of the remaining EBL material (e.g., PANI/PMMA blends). PANI based EBL systems can also be formulated with lower glass transition temperatures (e.g., relative to PANI protonated with CSA), which can allow a thermal embossing process (e.g., used to form nanotextured features) to be performed at lower temperatures potentially minimizing thermal degradation of PANI. One example of such a system is PANI protonated with 1,2-benzenedicarboxylic acid, 4-sulfo, 1,2-di(2-ethylhexyl) ester (“DEHEPSA”) dissolved in dichloroacetic acid (“DCC”) blended with PMMA plasticized with dibutyl phthalate. An alternate system is a class of polyaniline-sulfosuccinates which have sufficiently low glass transition temperatures to produce stretchable polyanilines that retain their high conductivity. Other sulfonic acids such as dodecylbenzenesulfonic acid can also plasticize PANI/PMMA.

In some embodiments, various surface treatments or combinations of materials can be included to improve the properties of the PANI-based EBLs, such as to lower the contact resistance (or barrier to charge extraction) between PANI and an organic semiconductor material. The surface can be redoped with PANI using solution blending, chemical polymerization, or vapor deposition. In some embodiments, the host material of the EBL is controllably dissolved at the surface, which can leave a greater concentration of PANI-CSA. For instance, a conductive dopant/host matrix EBL system surface can be exposed to one or more solvents or solvent combinations where there is a large differential in the solubility between the host matrix and conductive dopant. For example, it has been found that exposing a surface to 1:3 methyl isobutyl ketone (“MIBK”): isopropyl alcohol (“IPA”) can preferentially remove PMMA, providing a richer PANI surface that can enhance the degree of charge extraction at the surface.

Non PANI-based EBLs can also be utilized. For instance, conductive plastics have been prepared by using polymeric acid dopants such as poly(methyl methacrylate-co-p-styrenesulfonic acid) or poly(2-acryamido-2-methyl-1-propanesulfonic acid) which have demonstrated improved conductivities and temperature stability compared to PANI based systems protonated with small molecule acids such as CSA. Other conductive plastics that can be used in an EBL include a thermal setting conductive polymer system doped with PEDOT:PSS, a hole conducting EBL material more commonly used in organic bilayer solar cells, due to its higher work function. Conductive UV curable antistatic coatings doped with PEDOT can be used, and can be patterned using UV based nano-imprint. Conductive plastic can also be formed using dopants dispersed rather than dissolved in a host matrix, provided the dopant materials are sufficiently small relative to the characteristic dimensions of the nanotextured features. For instance, conductive plastics can be formed using colloidal polyaniline blended with PMMA. Conductive plastics can also include materials formed from carbon nanotubes dispersed in various host matrices.

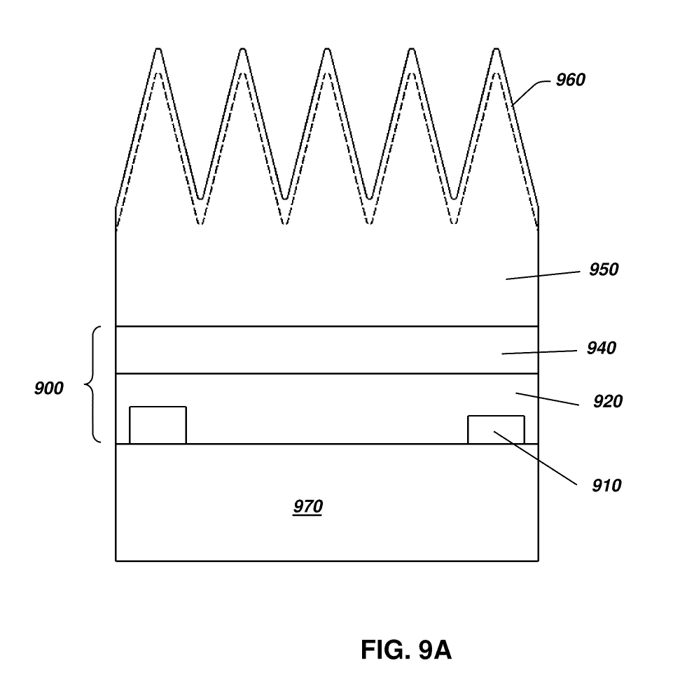

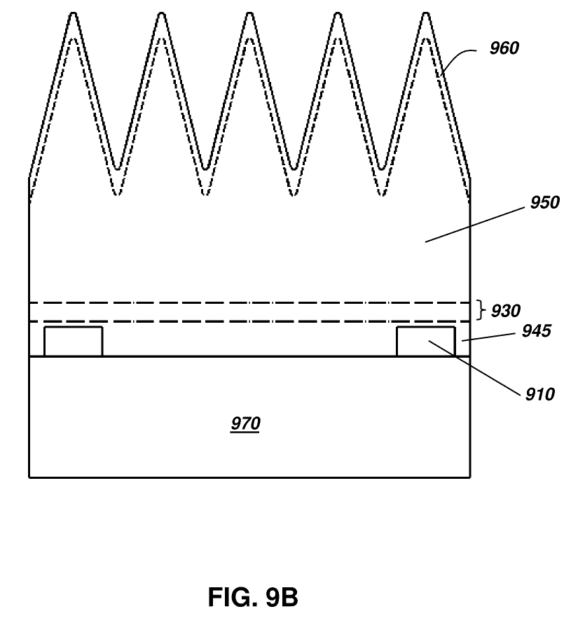

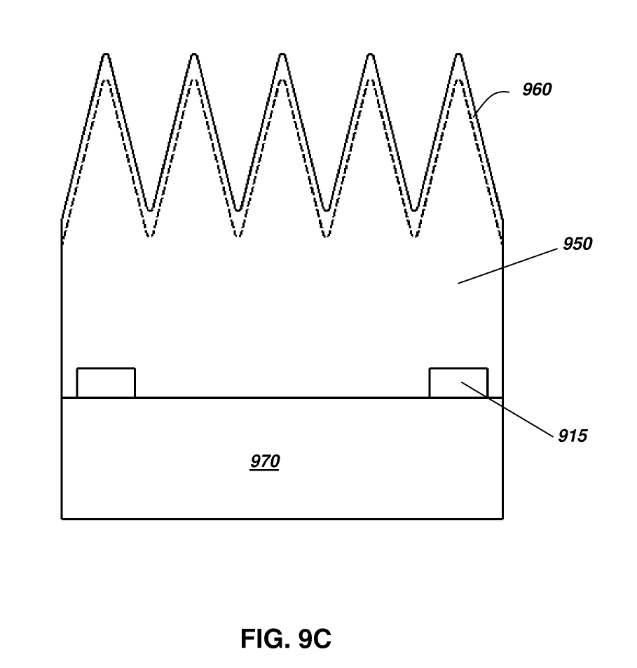

In some embodiments, various combinations of anode and hole conducting exciton blocking materials, with or without surface treatments to lower contact resistance, can be used in a photon processing device. As exemplified in FIG. 9A, an anode 900 can be formed from metal bus lines 910, a transparent conductive oxide 920 such as ITO, and a conductive polymer 940 such as PANI or PEDOT. The imprintable or patternable conductive plastic 950, serving as an EBL, can be coated over the anode 900. After patterning, the surface 960 of the conductive plastic can be modified to lower contact resistance. In an alternative embodiment, as depicted in FIG. 9B, a device is formed similar to that shown in FIG. 9A, except that no transparent conductive oxide is utilized. Depending on the phase compatibility of the conductive plastic 950 and conductive polymer 945, there may be a region of intermixing 930. In another alternative embodiment depicted in FIG. 9C, the anode is simply metal bus lines 915.

While any number of techniques can be utilized to form nanotextured surfaces on an EBL, in some embodiments nanoimprint, or embossing, is utilized. An imprint step is also amenable to high throughput roll-to-roll processing since no high resolution alignment step is necessarily required. The imprint step can also be performed without significantly degrading yields. In some embodiments, a mold master is utilized to contact the EBL, transferring a nanotextured pattern onto the surface of the EBL. Particles, which may transfer from the mold master to the device, are not expected to short-circuit the device. Rather the small loss in surface area is more than compensated by utilizing multi-dimensional nanoimprinted structures to increase interfacial density.

To date, exciton blocking layers directly patterned in organic based solar cells by imprint lithography are not known in the prior art. The two principle conductive polymers, PEDOT:PSS and polyaniline, which have been used as exciton blocking layers in organic devices, are sufficiently absorptive that over the thicknesses targeted, significant optical losses occur. In addition, these materials, do not have well defined glass transition temperatures where the viscosity changes markedly. Because of this property, they are not amenable to high resolution patterning directly using thermal embossing techniques.

Consistent with some embodiments, when thermal imprinting includes temperature cycling, thermal management can reduce embossing times significantly. For instance, 100 nm diameter pillars that are 100 nm deep in PMMA can be formed using 5 second imprint times by only heating the mold master. As well, nanoimprint processes can include using a roller based process. A mold master can first be produced by imprinting the desired pattern from a planar hard-mask into a thin layer of polymer such as a poly(urethaneacrylate) coated on a PET membrane. The patterned membrane can then rolled over an elastomeric drum. Using separate heating and cooling rollers, thermal imprinting of sub 100-nm-scale features at 140° C. in polystyrene can be performed at substantial feed rates (e.g., 5 cm/sec).

The use of a conductive UV curable nanoimprint resist as an EBL can be advantageous since such materials typically exhibit lower viscosities compared to PMMA at typical thermal imprint temperatures. As well, lower pressures can be used and/or the nanoimprint resist can be dispensed in droplets rather than coated in a separate step. In UV-based imprint, the fluid is typically squeezed out laterally as a mold descends into the resist. Alternatively, as no high-resolution alignment step is required, a higher throughput roller based process can also be utilized. The reduced contact area along one dimension enables more efficient fluid displacement. This technique has demonstrated 50 nm resolution.

Micromachining techniques developed in semiconductor fabrication can be used to fabricate high aspect ratio nanotextured (e.g., tapered structures) mold masters at the 100 nm scale dimensions. Conducted experiments have shown that such micromachining can be successfully achieved. For example, tapered wedges have been fabricated in silicon as described in the examples herein. The structures were etched in a SF₆ plasma through a hydrogen silsesquioxane etch mask patterned using a 157 nm based interference exposure tool. The method relied on the differential between the lateral etch rate of the mask, to the vertical etch rate of the underlying silicon substrate. Others have manufactured higher aspect ratio cones (3:1) with sub-100 nm periods in quartz using fluorocarbon based plasma etching through a patterned chrome mask. This type of master could be used for performing the imprint step using UV curable nanoimprint resists.

The shape of a mold master can be any shape that can be utilized as a nano-sized feature in the EBL. When tapered structures are utilized, perfectly shaped cones and/or wedges need not be the only possible structures. Other tapered structures can be pyramidal, or have a flat, or rounded top. The walls of the structure can be curved rather than linear, and even have a reentrant structure. Well established electromagnetic simulation techniques based on rigorous coupled wave analysis (“RCWA”) or finite difference time domain (“FDTD”) algorithms can be used to select the EBL geometry to enhance optical coupling into the active organic semiconducting materials for given material optical properties and spectral characteristics of the input source. The structure can also be further refined to account for variations in growth rate along different sloped portions, which can be desirable to improve optical coupling in different portions of the device.

A variety of types of organic semiconductor materials can be used to form a composition that conforms with a shape having nanotextured features. For instance, with respect to FIGS. 2A and 2B, a number of n-type and p-type organic semiconductors, such as those routinely used in solar cells and/or organic LEDs, can be utilized as the organic semiconductor layers 240, 245, 250, 255 depicted therein. In some embodiments, copper-phthalocyanine (“CuPc”) can be utilized as a one type of organic material and fullerene (“C₆₀”) can be used as another type of organic material to form a heterojunction. Such embodiments can be advantageous due to their complementary absorption properties and the large exciton diffusion length in C₆₀. Other potential non-limiting combinations are shown in Table 2 below.

TABLE 2
Materials for Single Heterojunction Organic Semiconductor Structures
Material System: Single Junction

ITO/30 nm CuPc/50 nm PTCBI/Ag
ITO/25 nm CuPc/35 nm PTCDA/In
ITO/50 nm PTCBI/50 nm CuPc/Au
ITO/15 nm CuPc/6 nm PTCBI/15 nm BCP: PTCBI/80 nm Ag
ITO/PEDOT: PSS/50 nm CuPc/50 nm PTCBI/Ag
ITO/PEDOT: PSS/50 nm PTCBI/50 nm CuPc/20 nm Au
ITO/PEDOT: PSS/27 nm CuPc/18 nm PTCDI/20 nm PTCBI/20 nm Ag
ITO/40 nm PEDOT: PSS/45 nm Pentacene/45 nm PTDCI-C₁₃H₁₇/
8 nm BCP/60 nm Ag
ITO/90 nm V4T/90 nm PTCDA/Al
ITO/90 nm V5T/90 nm PTCDA/Al

Some embodiments include utilizing a semiconductor composition formed from CuPc and perylene derivatives, two photochemically stable blue and red dyes with complementary absorption properties. Other CuPc/perylene structures based on close relatives of PTCDA can also be used. In another embodiment PTCDA and pentacene can be utilized, an organic semiconductor more commonly used in organic thin-film transistors (“OTFT”) due to its high mobility. In organic solar cells, it has the potential advantage of a large exciton diffusion length (estimated to be 65 nm). It can be deposited at relatively high rates (0.9 nm/s) due to its low heat of vaporization. In yet another embodiment, a hetero structure can be formed between PTCDA and vinyl-quarterthiophene derivatives. Polythiophenes exhibit relative stability in oxygen, and high mobilities. Polymeric forms [regiorandom poly(2,5-thieneyl-3′-vinyl-2′,5′-thienyl)] can act to stabilize bilayer heterojunctions formed with C₆₀ derivatives.

In some embodiments, deposition of organic materials in bilayer herterojunction devices can be performed by thermal evaporation or OVPE, which can utilize a slow nitrogen flow to produce more conformal coverage. Deposition conditions can be varied to provide roughness or protrusions on a more atomic scale to increase the overlap of n and p materials at the junction. Solution based techniques can also be employed using dissolved semiconductors or more soluble precursors which are subsequently thermally converted to semiconductor form. Atomic layer deposition techniques can also be employed to sequentially add molecular scale films from solution or from the vapor phase.

With respect to embodiments utilizing bulk heterojunction materials, such as those depicted in FIGS. 4A and 4B, a number of materials can be utilized. Some non-limiting examples include phenylene vinylene derivatives, such as alkoxy-poly(para-phenylene vinylene) (“MDMO-PPV”), methanofullerene derivatives, such as [6,6]-phenyl-C₆₁-butyric acid methyl ester (“PCBM”), and polythiophene derivatives such as regioregular poly(3-hexylthiophene) (“P3HT”). Material can be deposited in a number of different ways such as spin casting or codepositing from the vapor phase. The bulk heterojunction can also be deposited between doped wide-gap transport layers. In some embodiments, a conformal film is deposited, which can provide a shorter path for photogenerated charge to flow to an electrode, e.g., as shown in FIG. 4A.

A variety of materials can be utilized in an electron conducting EBL composition. The material can be chosen to prevent contamination or damage to the underlying semiconducting layers during cathode deposition. As well or in addition, the thickness of an electron conducting EBL can be chosen to reduce absorption losses while maintaining a sufficient protective barrier. In some embodiments, bathocurproine (“BCP”) can be utilized as at least a portion of an EBL. A thermally evaporated film, 10-20 nm thick, can be used. Conductive organic polymers such PEDOT, PEDOT based derivatives, polyaniline, polyaniline derivatives, or conductive plastics derived from the aforementioned materials can also be used. In these instances, solventless methods exist for depositing PEDOT or PANI. Each can be deposited from the vapor phase. In another example, a solventless, PANI based epoxy system curable at 65° C. can be used, which is not expected to distort the underlying hole conducting exciton blocking layer where the glass transition temperature of common host matrix materials such as PMMA is above 100° C.

In some embodiments, a combination of deposition techniques can be used to form an EBL. For example with reference to FIG. 5, an anode 520 is deposited on a substrate 510. A hole conducting EBL 530 having nanotextured features is deposited and patterned on the anode 520. P-type layer 540, and n-type layer 550 are deposited on, and conform with, the nanotextured features of the hole conducting EBL 530. A high conductivity conformal PEDOT or PANI thin-film 560 can first be deposited from the vapor phase, followed by liquid phase coating and patterning of an epoxy based imprintable conductive plastic 580. Conductive plastic forms can also be deposited from the molten phase, and subsequently patterned using thermal imprint techniques. PEDOT or PANI based materials can also be applied using solvents by tailoring them accordingly to maintain the integrity of previously defined layers. Combinations of the above materials can also be used.

For an anode, a variety of suitable materials can be utilized in the embodiments disclosed herein. Low-to-medium work function metals such as Ca, Ag, Mg_{0.9}Ag_{0.1} or Al are typically used for the final electrode. With some metals, such as Al, nanometer scale layers of LiF are first deposited.

In some embodiments, an organic devices can be sealed with a glass capping layer to prevent the inter-diffusion of water vapor and oxygen which in the presence of light can degrade performance. Ultra-high diffusion barrier thin-films have been developed, which can be utilized in this capacity. These films employ alternating layers of inorganic and organic materials such as polyethylene and alumina to reduce pinholes.

### EXAMPLES

The following examples are provided to illustrate some embodiments of the invention. The examples are not intended to limit the scope of any particular embodiment(s) utilized.

### Example 1

### Preparation of Exciton Blocking Layers

In the examples herein, PANI/PMMA blends were prepared according to the following procedure. In a first step, PANI-CSA dispersed in m-cresol was prepared by separately baking 1.5 g of 10,000 MW PANI and 1.5 g CSA in a nitrogen purged oven at 80° C. for 2 hours to dry out samples. Based on the molecular weight of the repeating group of PANI (PhN) [PhN═C₆H₄NH_{0.5}=90.5 g/mole] and CSA [C₁₀H₁₆O₄S=232.3 g/mole], a 1:2 molar ratio of CSA to PhN mixture was produced by mixing 1.092 g of the dried PANI and 1.34 g of the dried CSA. 1.275 g of the PANI:CSA mixture was added to 61 g of m-cresol, and agitated in an ultrasonic bath for 48 hours. The solution was centrifuged, and the solid residual discarded. In a second step, PMMA was prepared by dissolving 10 g of 100K PMMA in 100 g of m-cresol (10% w/w).

PANI-CSA doped PMMA mixtures were produced using the two preparations described above, combined in proportions as documented in Table E1 below.

TABLE E1
PANI-CSA/PMMA Mixture Combinations

| | | |
|---|---|---|
| 2% PANI-CSA in | 10% PMMA in | |
| m-cresol | m-cresol | % PANI-CSA to |
| (step 1) | (step 2) | total solids |

| | | | |
|---|---|---|---|
| 10 | g | 10 g | 20% |
| 5 | g | 10 g | 10% |
| 3.5 | g | 10 g | 7% |
| 2.5 | g | 10 g | 5% |
| 1 | g | 10 g | 2% |
| 0.5 | g | 10 g | 1% |
| 0.25 | g | 10 g | 0.5% |

### Example 2

### Conductivity Calculations and Measurements

An estimate of the conductivity for a conductive plastic as utilized in a device as shown in FIG. 10 was calculated using Ohm's Law. Each tapered structure was assumed to be a cone. From Ohm's Law, the voltage drop, V_{drop}, across the EBL was related to the material's conductivity, σ, by:

$${V}_{drop} \sim \frac{{η}_{cell} {F}_{solar} {A}_{cone}}{{V}_{PD}} \frac{L}{σ {A}_{base}} \qquad ( 2.1 )$$

where definitions of the various parameters are listed in Table E.2. In Eqn. 2.1, the first product term specifies the current, and the second the resistance. To estimate the order of magnitude for the conductivity, it was assumed the cone has a radius of 50 nm and is 200 nm tall. The characteristic length scale was conservatively estimated as 500 nm to account for residual layers up to 300 nm. For the assumed values in the Table E.2, the voltage drop through the EBL scales as:

V_{drop}˜2.67 μV Ω⁻¹ cm⁻¹/σ. (2.2)

TABLE E2
Geometrical and Device Performance Parameters

| | | |
|---|---|---|
| Symbol | Definition | Assumed Values |

| η_{cell} | Solar cell efficiency | 0.10 | |
|---|---|---|---|
| Fₛₒₗₐᵣ | Solar flux | 1000 | W/m² |
| A_{cone} | Surface area of cone | 1/3*2π (50 nm) (200 nm) | |
| V_{PD} | Operating voltage of device | 0.5 | V |
| L | Length scale | 500 | nm |

| | | |
|---|---|---|
| A_{base} | Area of base of cone | π (50 nm)² |

Based on this analysis, conductivities at or above ˜10⁻⁴Ω⁻¹ cm⁻¹ can limit ohmic losses to a few percent of typical device operating voltages (˜0.3-0.5V).

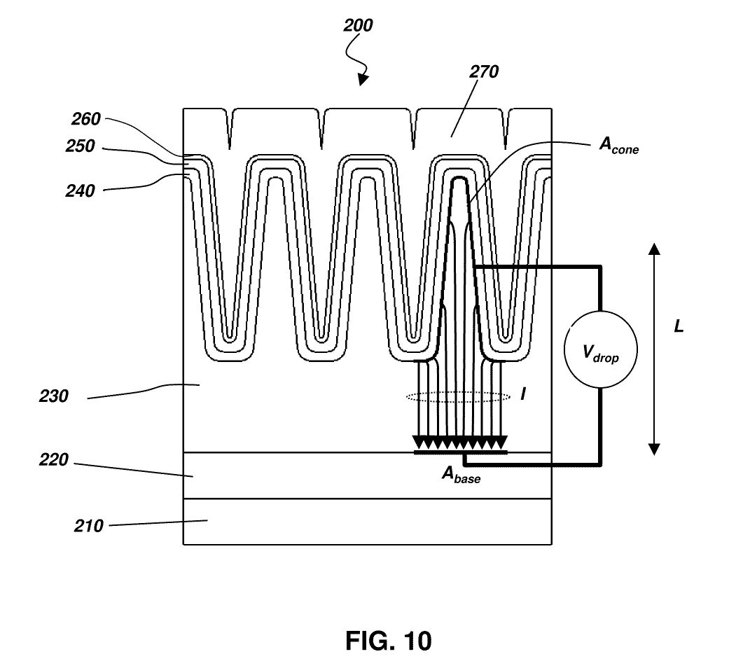

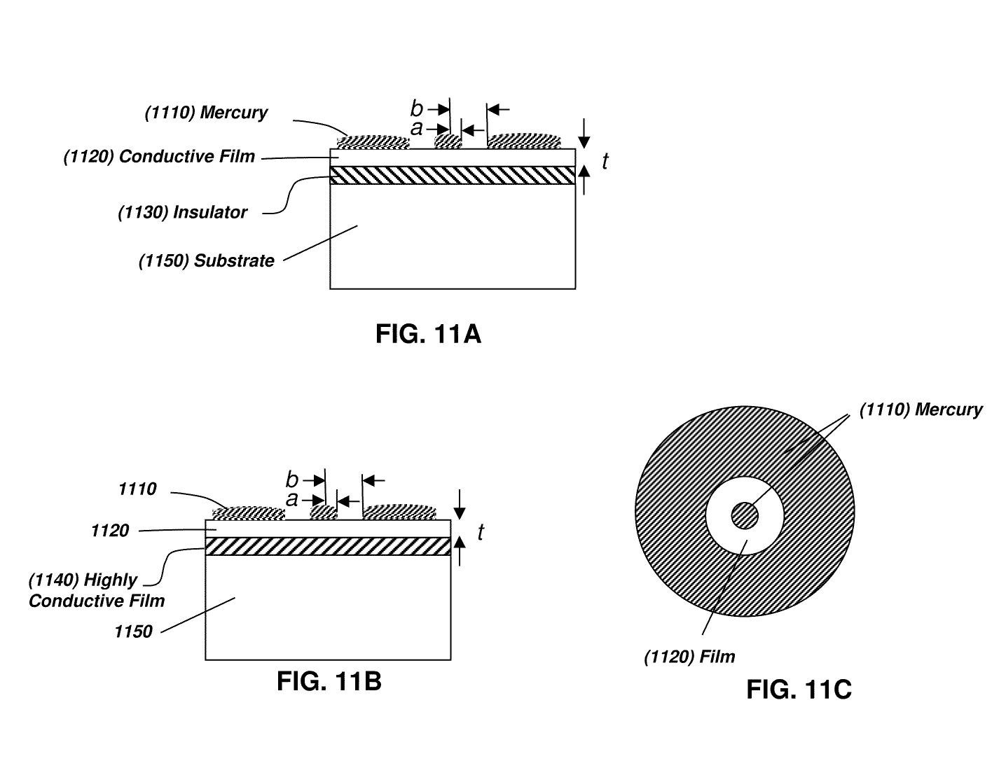

We evaluated conductivities on thin PANI/PMMA films by using a current-voltage (I-V) two-point probe station using a ring-type electrode. To prevent damage to the PANI/PMMA thin-film 1120, mercury drop contacts 1110 were used. By casting films on either a non-conductive 1130 or highly conductive substrate or film 1140, both lateral and vertical conductivities can be collected. FIGS. 11A and 11B show schematic side representations of the film stack arrangement for lateral and vertical conductivity measurements, respectively. The inner contact radius a is 462 microns and the outer contact's inner radius b is 800 microns. For the lateral measurements the PANI-PMMA film was spun on silicon oxide, while for the vertical measurements the film was spun on ITO or platinum. FIG. 11C provides a top view of the geometry of the mercury contacts in both cases depicted in FIGS. 11A and 11B. Films were spin coated (between 2,000 and 3,000 rpm), and baked at 160° C. for 4 minutes to drive out the coating solvent. Film thicknesses t were measured on oxidized silicon wafers, and assumed to not vary on different substrates or films.

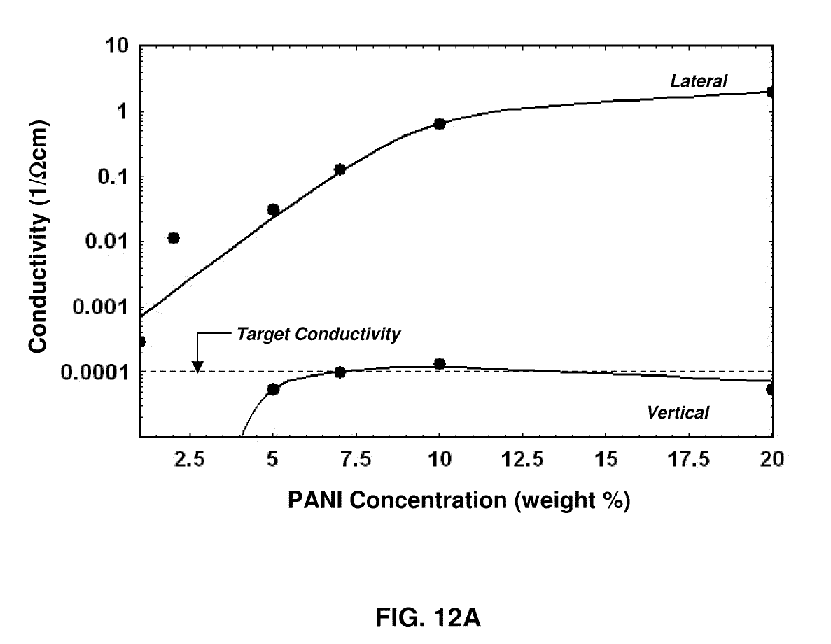

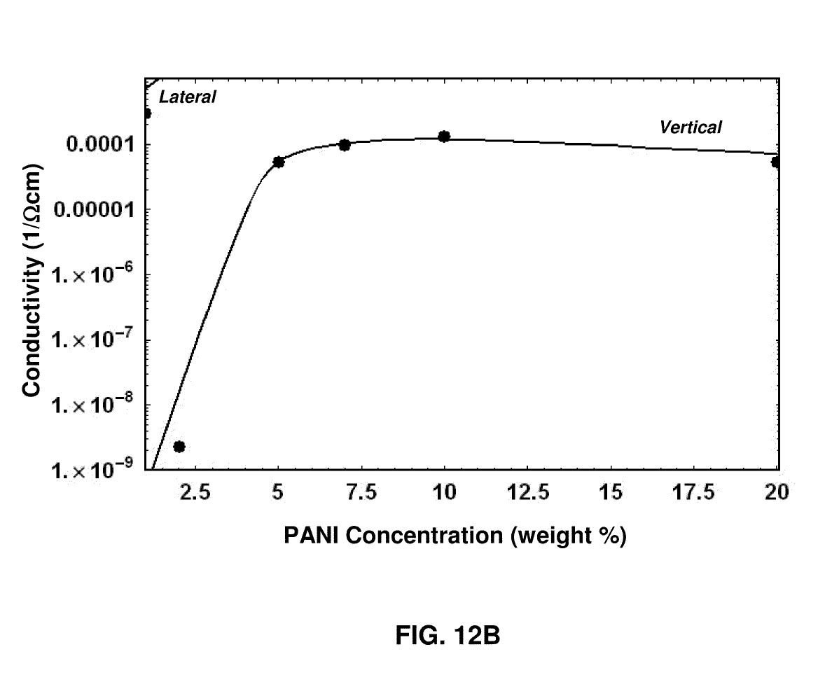

The results of the conductance measurements were derived by analyzing the slope of the I-V traces. FIGS. 12A and 12B provide the results of conductivity as a function of % PANI dopant concentration in PMMA. As reported in the literature, the conductivity increases exponentially at low dopant concentrations and then eventually saturates. As shown in FIG. 12A, a large anisotropy is observed in both the percolation threshold where conductivity increases rapidly, and magnitude in lateral and vertical current flow for spin-coated films. FIG. 12B provides an expanded y-axis scale for the trace corresponding to the vertical conductivity measurements. Since charge primarily flows vertically in the device, doping levels at or above 5% can limit ohmic losses.

### Example 3

### Temperature Stability

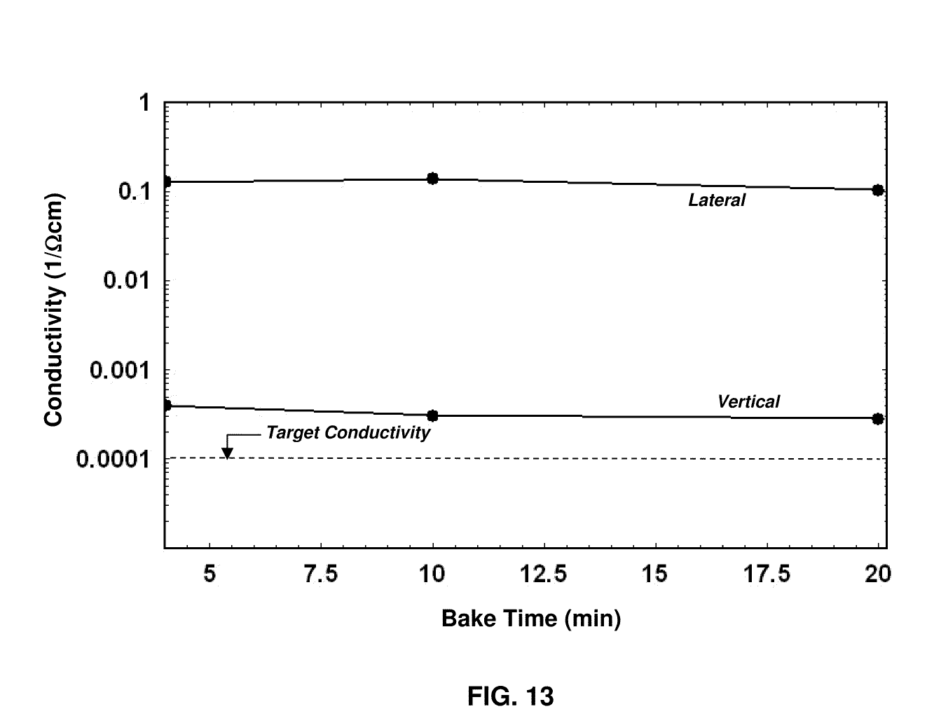

Lateral and vertical conductivity measurements were performed as a function of bake time for 7% doped PANI-PMMA. All films were spun at 2K RPM on glass (lateral) or platinum (vertical) coated glass substrates, and baked at 160° C. on a hot-plate. As documented in FIG. 13, we found no significant degradation in bulk conductivity for prolonged heat treatments up to 20 minutes, at 160° C.

### Example 4

### High Resolution Patterning

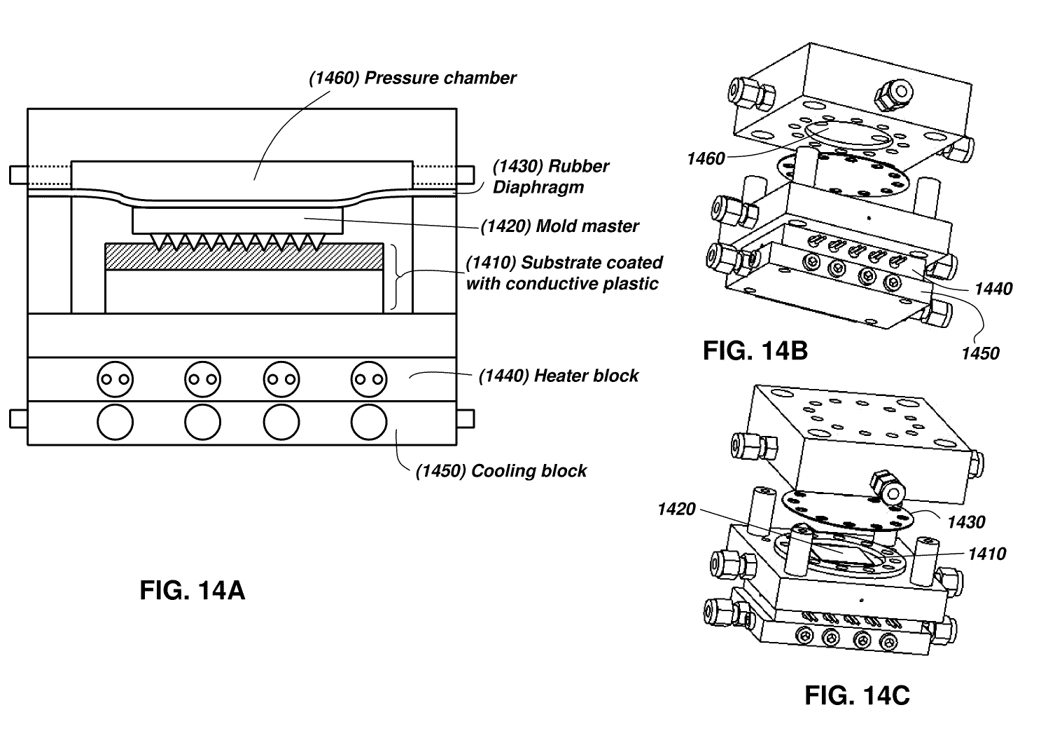

PANI/PMMA mixtures can be patterned at sub-100 nm scale resolutions using thermal imprint techniques. A schematic representation of several views of a tool for embossing is shown in FIGS. 14A-14C. A pressurized diaphragm provides a uniform compression force between the mold master and substrate coated with a thin-film of the PANI/PMMA mixture. The underside of the cell is heated to achieve temperatures above the glass transition temperature of the plastic.

Mold masters for imprinting the plastic mixtures were fabricated in silicon using a two step procedure. First, a 60 nm thick film of hydrogensilsesquioxane (“HSQ”) (Dow Corning FOx Series spin-on-glass) dissolved in MIBK was spin casted on a silicon substrate, the substrate being precleaned using a standard He/O₂ ash treatment for 5 minutes. Baking was performed at 130° C. for 2 minutes to remove residual solvent. An interference based optical lithography tool operating at 157 nm was used to expose a 90 nm period pattern onto the HSQ film at a dose of 500 mJ/cm². 2.6 N tetramethyl ammonium hydroxide was used to develop the exposed HSQ for five minutes, following by a deionized water rinse.

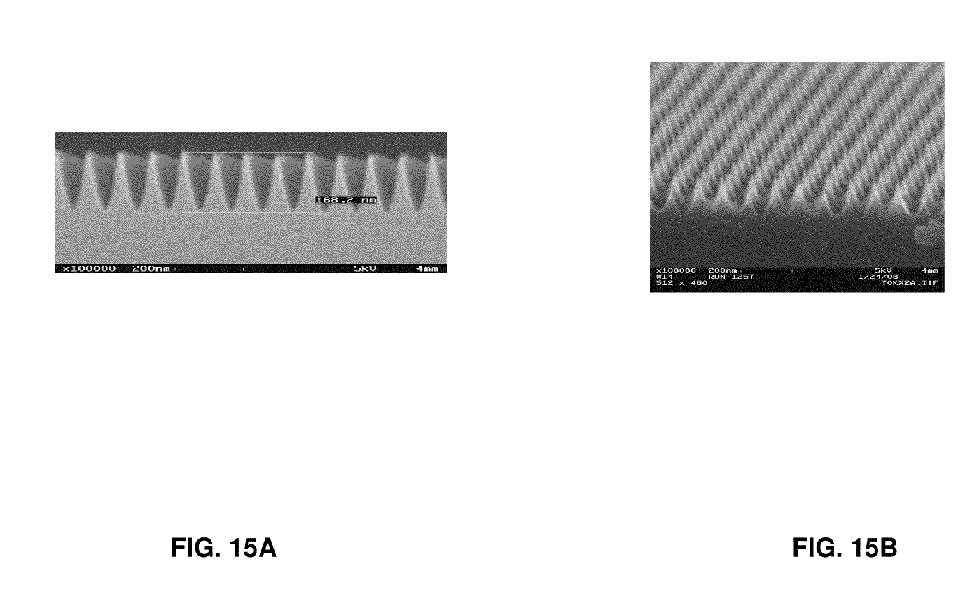

After HSQ patterning, wedges were formed by etching the exposed silicon in a 90% SF₆/10% O₂ reactive ion etcher at 60V bias (25 mTorr flow). Under these conditions, there was a large differential in vertical etch rate in silicon compared to lateral etch rate in HSQ. As the etch progresses, a wider opening formed resulting in a tapered structure in the underlying silicon substrate. In a similar fashion, 3D cones were produced using 2D arrays of contact holes defined in the HSQ etch mask. Examples of two dimensional wedges and three dimensional cones are shown in FIGS. 15A and 15B.

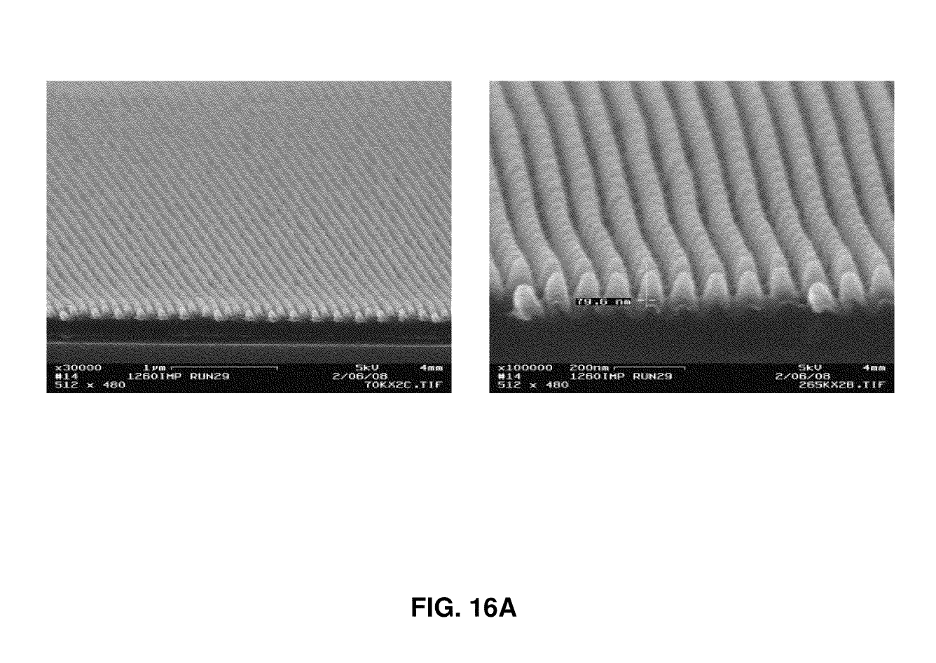

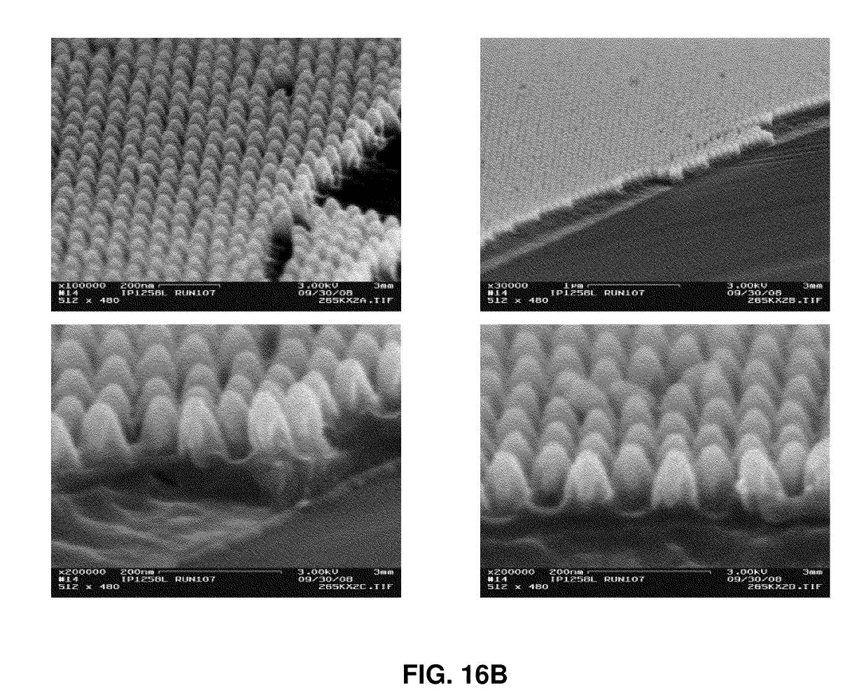

FIGS. 16A and 16B shows cross-sections of replicated nanocones in 300 nm thick films of PMMA and 20% doped PANI/PMMA, respectively. The films were prepared by spin-coating solutions at 2.5K RPM on silicon substrates cleaned for 5 minutes in a plasma asher. The cast films were baked at 160° C. for 4 minutes to drive out the coating solvent prior to embossing. The master was cleaned in a H₂O₂/H₂SO₄ mixture for 10 minutes, and subsequently coated in an evacuated chamber with a monolayer of the release layer, (Tridecafluoro-1,1,2,2-tetrahydrooctyl)trichlorosilane. To imprint the structures, and with reference to FIGS. 14B and 14C, the mated mold master 1420 and substrate coated with the conductive PANI/PMMA plastic 1410 were heated to 160° C. using integrated heater block 1440. They were then pressed together at 300 psi for 2 minutes by pressurizing chamber 1460, causing rubber diaphragm 1430 to expand against the mated pair 1410 and 1420. While under pressure, the samples were cooled to 35° C. using integrated cooler block 1450, before unloading and separating the samples. The results demonstrate highly textured features can be imprinted in doped PANI/PMMA at the periods and depths necessary to achieve efficiency enhancements based on simulation results. Similar results have been found on ITO coated substrates. In these cases, the ITO substrates were cleaned with a 3 minute plasma ash prior to coating.

### Example 5

### Optical Transparency

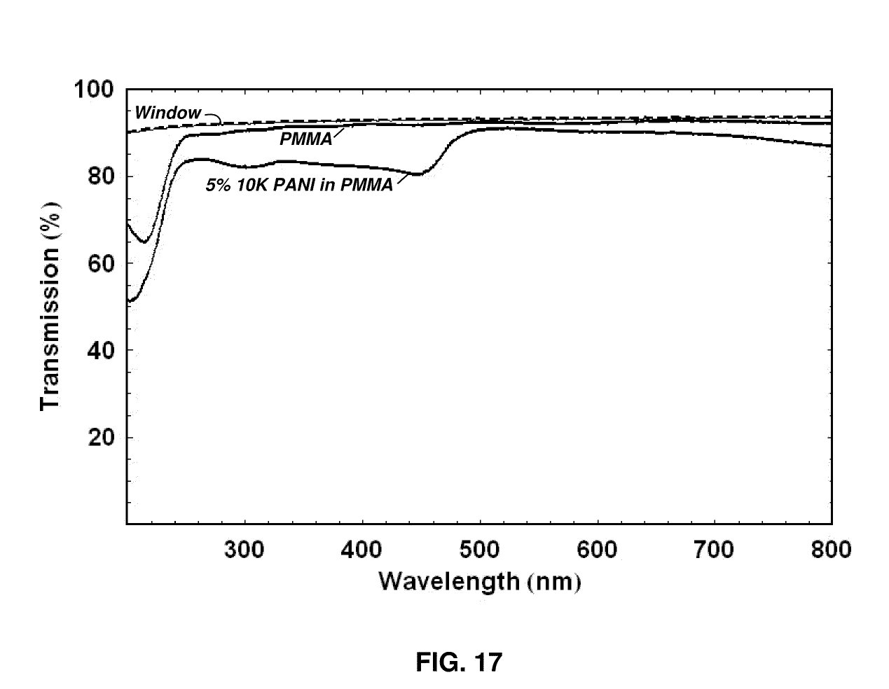

The spectral transmission of a 5% doped PANI/PMMA thin-film over a portion of the solar spectra was measured for a 500 nm thick film. The film was spin coated on a fused silica window, and baked for 4 minutes at 160° C. to drive out the coating solvent. FIG. 17 presents a graph of the spectra. Based on the measurements, the estimated absorption losses integrated over the solar spectrum from 300 to 800 nm at various doping levels for a 500 nm thick film is shown in Table E.5. For comparison, the absorption losses for a pure PANI film, 100 nm thick, are also shown.

TABLE E5
Integrated Absorption Loss from 300 nm to 800 nm

| | | |
|---|---|---|
| PANI Dopant | | |
| Level in PMMA | Thickness (nm) | Absorption Loss (%) |

| | | |
|---|---|---|
| 0% | 500 nm | 1.2% |
| 2% | 500 nm | 24% |
| 5% | 500 nm | 5.7% |
| 10% | 500 nm | 11% |
| 20% | 500 nm | 20% |
| 100% (pure PANI) | 100 nm | 20% |
| 100% (pure PANI) | 500 nm | 62% |

### Example 6

### Preparation of PANI Rich Surfaces

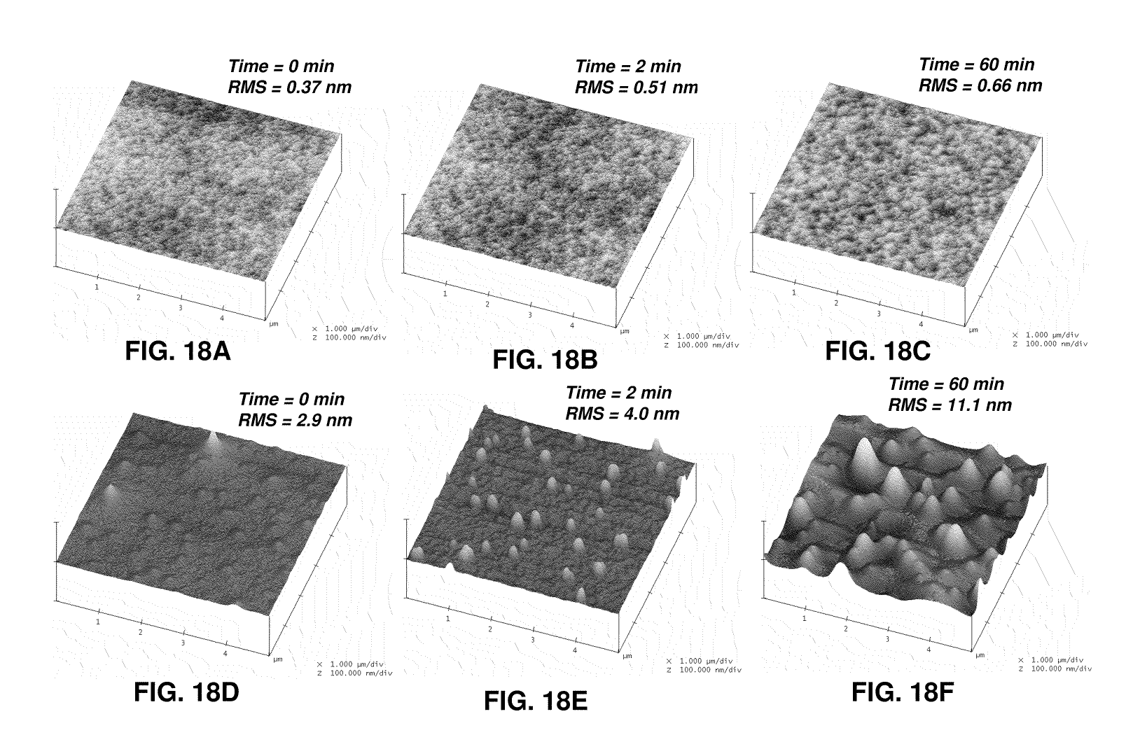

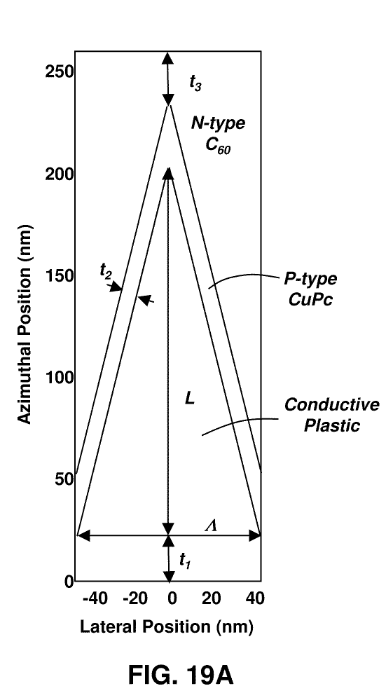

PANI rich surfaces were prepared by controllably stripping PMMA in 1:3 MIBK/IPA solutions. The AFM images shown in FIG. 18 depict the surface morphology as a function of immersion time. All materials were prepared by spin coating PMMA and 7% dopant PANI/PMMA films on ashed silicon substrates. After coating, the samples were baked at 160° C. for 4 minutes to drive out the coating solvent. In general, as indicated by the RMS roughness values by each image in FIG. 18, the roughness increase is much more pronounced on PANI/PMMA films compared to undoped PMMA films demonstrating PMMA can be selectively removed in PANI/PMMA.

### Example 7

### Simulations of Organic Solar Cell Performance

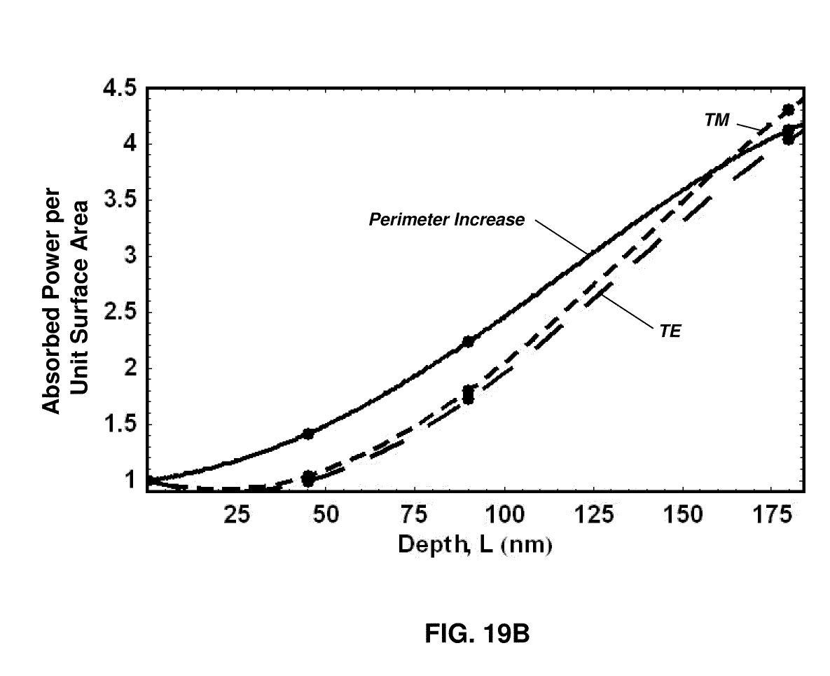

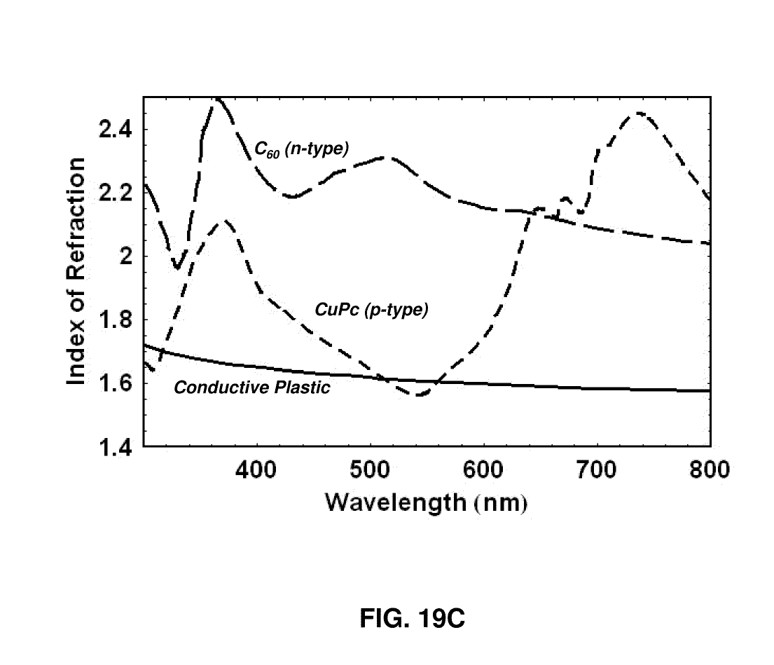

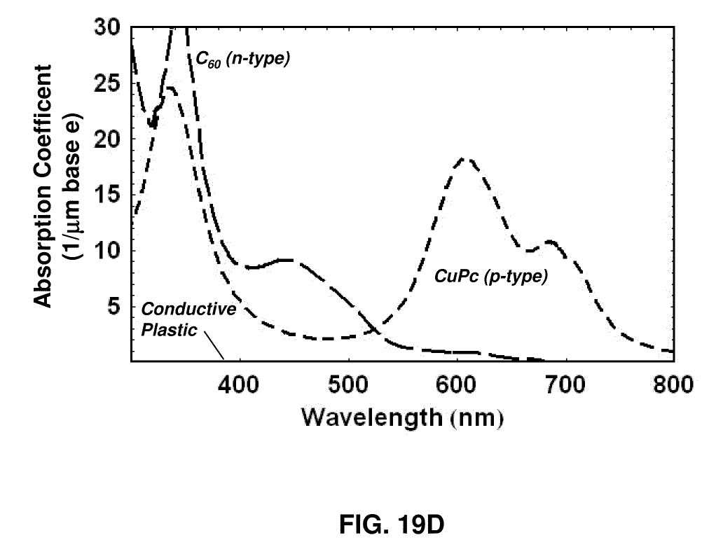

Simulations of the power performance of organic solar cells utilizing tapered nanostructure features were conducted. First order estimates of the absorbed power at a heterojunction interface between organic semiconducting films compared to a one-dimensional planar device can be calculated. FIGS. 19A-19D show simulation results using rigorous coupled wave analysis on a two-dimensional model system irradiated at normal incidence over the terrestrial portion of the spectrum from 300 to 800 nm. The geometry of a two-dimensional tapered nanostructure feature is depicted in FIG. 19A. The dimensions of the two-dimensional features are shown in Table E7 below.

TABLE E7
Dimensions of Simulated Structure

| | |
|---|---|
| t₁ | 20 nm |
| t₂ | 10 nm |
| t₃ | 40 nm |
| Λ | 90 nm |

In the simulations, the cathode, electron conducting EBL, and anode are not included. Accordingly, thin-film interference effects created by these films are removed from the analysis, allowing the salient features of the architecture to be ascertained. Reflectivity losses have only been subtracted out in the planar case. Surfaces are assumed to be optimized with a perfect broadband anti-reflective (“AR”) coating. The materials used in the simulation are CuPc for the p-type semiconductor film and C₆₀ for the n-type layer. For the hole conducting EBL, we assume the conductive plastic is relatively transparent and has an index of approximately 1.6 in the visible spectrum. Indicies of refraction and absorption coefficients (base e) for the representative materials used in the simulations are shown in FIGS. 19C and 19D. Due to the extended simulation times (days), the absorbed power is integrated over the visible solar spectrum using coarse, 100 nm steps in incident wavelength.

The results of the simulations are shown in FIG. 19B. The curves plot the relative enhancement in power absorption per unit surface area at the interface between n- and p-type material using a two-dimensional geometry relative to a planar geometry as a function of depth L In general, the absorbed power at the interface between n- and p-type material scales roughly in proportion to the increase in perimeter, with a slight split between the transverse electric and transverse magnetic components at higher aspect ratios. The slightly higher efficiency gain compared to the perimeter increase for high aspect ratio wedges may be due to light trapping, as scattered light may penetrate the interface at adjoining wedges.

The simulations predict a three- to four-fold increase in absorbed power at the interface per unit surface area relative to the planar case for wedges with 2:1 aspect ratios and 90 nm lateral features. Higher gains may be possible in three-dimensional structures. For instance, from simple geometrical arguments, three-dimensional cones arranged on a hexagonal array have roughly a 50% (π/2) increase in surface area compared to wedges with the same lateral feature sizes and aspect ratios.

### EQUIVALENTS

While the present invention has been described in terms of specific methods, structures, and devices it is understood that variations and modifications will occur to those skilled in the art upon consideration of the present invention. As well, the features illustrated or described in connection with one embodiment can be combined with the features of other embodiments. Such modifications and variations are intended to be included within the scope of the present invention. Those skilled in the art will appreciate, or be able to ascertain using no more than routine experimentation, further features and advantages of the invention based on the above-described embodiments. Accordingly, the invention is not to be limited by what has been particularly shown and described, except as indicated by the appended claims.

All publications and references are herein expressly incorporated by reference in their entirety. The terms “a” and “an” can be used interchangeably, and are equivalent to the phrase “one or more” as utilized in the present application. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

What is claimed is:

1. A photon processing device, comprising:
a conductive substrate capable of conducting charge carriers, the conductive substrate comprising a textured surface comprising nanometer-scaled features; and
an organic semiconductive composition having at least a portion conforming to the textured surface, the semiconductive composition comprising at least one material forming at least a portion of a heterojunction.

2. The photon processing device of claim 1, wherein the photon processing device is configured as an organic solar cell.

3. The photon processing device of claim 2, wherein the textured surface comprises periodic structures including at least one of protrusions and indentations characterized by a pitch less than about a minimum visible solar spectrum wavelength divided by an index of refraction of the conductive substrate.

4. The photon processing device of claim 2, wherein the nanometer-scaled features are configured to direct solar radiation to the semiconductive composition.

5. The photon processing device of claim 2, wherein the conductive substrate comprises a material transparent to at least a portion of solar radiation.

6. The photon processing device of claim 2, wherein the organic solar cell is configured as a rolled up flexible structure capable of being unrolled and operable.

7. The photon processing device of claim 1, wherein the textured surface comprises periodic structures characterized by a pitch that is less than about 500 nm.

8. The photon processing device of claim 1, wherein the textured surface comprises a plurality of tapered structures.

9. The photon processing device of claim 1, wherein the nanometer-scaled features are two-dimensional.

10. The photon processing device of claim 1, wherein the nanometer-scaled features are three-dimensional.

11. The photon processing device of claim 1, wherein the organic semiconductive composition comprises at least one of a n-type material layer, a p-type material layer, and a bulk heterojunction material.

12. The photon processing device of claim 11, wherein the organic semiconductive composition comprises at least one p-type layer and at least one n-type layer.

13. The photon processing device of claim 12, wherein the at least one p-type layer and at least one n-type layer form a plurality of separate p-n junctions.

14. The photon processing device of claim 12, wherein at least one of the layers comprises a shape substantially conforming with the plurality of tapered structures.

15. The photon processing device of claim 12, wherein at least one of the layers exhibits a thickness less than about 100 nm.

16. The photon processing device of claim 15, wherein at least one n-type material layer and at least one p-type material layer each exhibit a thickness less than about 100 nm.

17. The photon processing device of claim 1, wherein the nanometer scaled features exhibit a height to pitch ratio of at least about 0.5:1.

18. The photon processing device of claim 1, further comprising:
electrodes electrically coupled to the conductive substrate and the semiconductive composition.

19. The photon processing device of claim 18, wherein at least one electrode is transparent to at least a portion of the solar radiation.

20. The photon processing device of claim 1, wherein the conductive substrate comprises a mixture of polymethyl methacrylate doped with polyaniline.

21. A photon processing structure, comprising:
an organic semiconductive composition comprising at least one layer comprising at least one of a n-type organic material and a p-type organic material, the at least one layer forming at least a portion of a heterojunction and conforming to features of a nanotextured surface, the features characterized by a pitch less than about 500 nm.

22. The structure of claim 21, wherein the features comprise tapered structures.

23. The structure of claim 21, wherein the features are two-dimensional.

24. The structure of claim 21, wherein the features are three-dimensional.

25. The structure of claim 21, wherein the at least one layer exhibits a thickness less than about 100 nm.

26. The structure of claim 21, wherein the organic semiconductive composition comprises at least one n-type material layer and at least one p-type material layer each exhibiting a thickness less than about 100 nm.

27. The structure of claim 21, wherein the features exhibit a height to pitch ratio of at least about 0.5:1.

28. A method of forming a photon processing device, comprising:
providing a conductive substrate comprising a plurality of nanostructures characterized by a pitch less than about 500 nm; and
coupling an organic semiconductive composition to the conductive substrate, the organic semiconductive composition comprising a n-type material and a p-type material, at least a portion of the organic semiconductive composition conforming with the plurality of nanostructures of the conductive substrate.

29. The method of claim 28, further comprising:
attaching at least one electrode in electrical communication with the conductive substrate and the organic semiconductive composition to form a photovoltaic cell.

30. The method of claim 29, wherein the step of attaching the at least one electrode comprises:
forming the conductive substrate on the at least one electrode surface.

31. The method of claim 30, further comprising:
providing another electrode in electrical communication with the organic semiconductive structure.

32. The method of claim 28, wherein the plurality of nanostructures comprise tapered structures.

33. The method of claim 28, wherein the conductive structure comprises a material capable of conducting at least one of holes and electrons.

34. The method of claim 28, wherein the step of providing the conductive structure comprises:
forming the plurality of nanostructures of the conductive structure by imprinting the conductive structure.

35. The method of claim 34, wherein the conductive structure comprises a polymethyl methacrylate doped with polyaniline.

36. The method of claim 34, wherein the step of forming the plurality of nanostructures comprises:
forming at least one of a two-dimensional nanostructure and a three-dimensional nanostructure.

37. The method of claim 28, wherein the step of coupling the organic semiconductive composition comprises:
depositing at least one n-type material layer and at least one p-type material layer such that at least one of the layers contacts the conductive substrate.

38. The method of claim 37, wherein the step of depositing comprises:
conforming at least one of the layers to the plurality of nanostructures of the conductive substrate.

39. The method of claim 37, wherein at least one of the layers has a thickness less than about 100 nm.

40. The method of claim 37, wherein the step of depositing comprises:
depositing at least one layer using at least one of organic vapor phase epitaxy and thermal evaporation.
